(19) United States
(12) Patent Application Publication
(10) Pub. No.: US 2026/0173667 A1
(43) Pub. Date: Jun. 18, 2026

(54) BARRIER PATTERN LAYER OF DISPLAY DEVICE AND ELECTRONIC DEVICE INCLUDING THE SAME

(71) Applicant: Samsung Display Co., LTD., Yongin-si (KR)

(72) Inventor: HYUN-BEEN HWANG, Yongin-si (KR)

(21) Appl. No.: 19/207,621

(22) Filed: May 14, 2025

(30) Foreign Application Priority Data
Dec. 18, 2024 (KR) 10-2024-0189664

(51) Int. Cl. H10K 59/124; H10K 59/121

(52) U.S. Cl. CPC H10K 59/124; H10K 59/1213

(57) ABSTRACT

A display device includes a transistor including an active pattern including an oxide semiconductor, a source region, a drain region, a channel region, and a boundary between the channel region and each of the source region and the drain region, respectively, a hydrogen-blocking barrier pattern layer which is on the active pattern and includes a first barrier pattern at the boundary between the channel region and the source region and a second barrier pattern at the boundary between the channel region and the drain region, a gate insulating layer on the active pattern, the first barrier pattern and the second barrier pattern, and a gate electrode on the gate insulating layer, and a light emitting element on the gate electrode.

This application claims priority to Korean Patent Application No. 10-2024-0189664, filed on Dec. 18, 2024, and all the benefits accruing therefrom under 35 U.S.C. § 119, the contents of which is hereby incorporated by reference for all purposes as if fully set forth herein.

### BACKGROUND

### 1. Field

Embodiments relate to a display device and an electronic device including the same.

### 2. Description of the Related Art

Organic light emitting display devices are self-emitting display devices which do not require a separate light source such as a backlight, are easy to reduce in thickness, and are suitable for implementing flexible display device. As such, the use of organic light emitting display devices is increasing.

In order to efficiently drive organic light emitting diodes at low power, organic light emitting display devices which include both silicon-based semiconductor devices and oxide-based semiconductor devices have been developed.

### SUMMARY

Embodiments provide a display device with improved reliability.

Embodiments provide an electronic device including the display device.

A display device according to an embodiment of the present disclosure includes a substrate, a transistor on the substrate and a light emitting element on the gate electrode. The transistor includes an active pattern including an oxide semiconductor and in which grooves are defined, a barrier pattern layer on the active pattern, a gate insulating layer on the active pattern, a first barrier pattern and a second barrier pattern and a gate electrode on the gate insulating layer. The active pattern includes a source region, a drain region, and a channel region between the source region and the drain region, and among the grooves, a first groove between the source region and the channel region, and a second groove between the drain region and the channel region. A barrier pattern includes the first barrier pattern in the first groove of the active pattern and the second barrier pattern in the second groove of the active pattern.

In an embodiment, a depth of each of the first groove and the second groove may be less than a thickness of the active pattern.

In an embodiment, each of the first barrier pattern and the second barrier pattern may contact the active pattern.

In an embodiment, the display device may further include a barrier layer which includes an inorganic material layer between the active pattern and the gate insulating layer, and extended further than the active pattern in a direction along the substrate.

In an embodiment, the barrier layer may extend into the first groove and the second groove. The first barrier pattern may be between the barrier layer and the gate insulating layer, in the first groove. The second barrier pattern may be between the barrier layer and the gate insulating layer, in the second groove.

In an embodiment, the barrier pattern layer may include a hydrogen-blocking material. The first barrier pattern which is in the first groove may block hydrogen diffusion from the gate insulating layer to the channel region via the source region. The second barrier pattern which is in the second groove may block hydrogen diffusion from the gate insulating layer to the channel region via the drain region.

In an embodiment, each of the first barrier pattern and the second barrier pattern may include a metal.

In an embodiment, each of the first barrier pattern and the second barrier pattern may include titanium or copper.

In an embodiment, the display device may further include an interlayer insulating layer on the gate electrode, a source electrode of the transistor which is on the interlayer insulating layer and connected to the transistor at the source region and a drain electrode of the transistor which is on the interlayer insulating layer and connected to the transistor at the drain region.

A display device according to an embodiment of the present disclosure includes a substrate, a transistor on the substrate and a light emitting element on a gate electrode. The transistor includes an active pattern including an oxide semiconductor, a source region, a drain region, and a channel region between the source region and the drain region, a barrier pattern layer on the active pattern, a gate insulating layer on the active pattern, a first barrier pattern and the second barrier pattern and the gate electrode on the gate insulating layer. The barrier pattern layer includes the first barrier pattern overlapping the source region of the active pattern and the second barrier pattern overlapping the drain region of the active pattern.

In an embodiment, the first barrier pattern and the second barrier pattern may contact an upper surface of the active pattern at the source region and the drain region, respectively.

In an embodiment, the display device may further include an interlayer insulating layer on the gate electrode, a source electrode of the transistor which is on the interlayer insulating layer and connected to the transistor at the source region a drain electrode of the transistor which is on the interlayer insulating layer and connected to the transistor at the drain region, a first through hole which is defined through a thickness of the first barrier pattern, exposes the source region to outside the first barrier pattern and in which the source electrode contacts the source region and a second through hole which is defined through a thickness of the second barrier pattern, exposes the drain region to outside the second barrier pattern and in which the drain electrode contacts the drain region.

In an embodiment, the barrier pattern layer may include a hydrogen-blocking material. A boundary may be defined between the channel region, and each of the source region and the drain region, respectively. the first barrier pattern may extend to the boundary between the channel region and the source region and block hydrogen diffusion from the interlayer insulating layer to the source region. The second barrier pattern may extend to the boundary between the channel region and the drain region and block hydrogen diffusion from the interlayer insulating layer to the drain region.

In an embodiment, each of the first barrier pattern and the second barrier pattern may include a metal.

An electronic device according to an embodiment of the present disclosure includes a display device and a processor which controls the display device. The display device includes a substrate, a transistor on the substrate and a light emitting element on a gate electrode. The transistor includes an active pattern including an oxide semiconductor, a source region, a drain region, a channel region between the source region and the drain region, and a boundary between the channel region and each of the source region and the drain region, respectively, a barrier pattern layer which is on the active pattern and includes a hydrogen-blocking material, a gate insulating layer on the active pattern, a first barrier pattern and a second barrier pattern and the gate electrode on the gate insulating layer. The barrier pattern layer includes a first barrier pattern which is disposed at the boundary between the channel region and the source region and a second barrier pattern which is disposed at the boundary between the channel region and the drain region.

In an embodiment, grooves may be defined in the active pattern. The grooves may include a first groove which extends to the boundary between the channel region and the source region and in which the first barrier pattern is disposed and a second groove which extends to the boundary between the channel region and the drain region, is spaced apart from the first groove and in which the second barrier pattern is disposed. The first barrier pattern which is in the first groove may block hydrogen diffusion from the gate insulating layer to the channel region via the source region. The second barrier pattern which is in the second groove may block hydrogen diffusion from the gate insulating layer to the channel region via the drain region.

In an embodiment, each of the first barrier pattern and the second barrier pattern may contact the active pattern.

In an embodiment, the display device may further include a barrier layer which includes an inorganic material layer between the active pattern and the gate insulating layer, extended into each of the first groove and the second groove, and extended further than the active pattern in a direction along the substrate, the first barrier pattern between the barrier layer and the gate insulating layer, in the first groove and the second barrier pattern between the barrier layer and the gate insulating layer, in the second groove.

In an embodiment, the display device may further include an interlayer insulating layer on the gate electrode, a source electrode of the transistor which is on the interlayer insulating layer and connected to the transistor at the source region, a drain electrode of the transistor which is on the interlayer insulating layer and connected to the transistor at the drain region, a first through hole which is defined through a thickness of the first barrier pattern, exposes the source region to outside the first barrier pattern and in which the source electrode contacts the source region and a second through hole which is defined through a thickness of the second barrier pattern, exposes the drain region to outside the second barrier pattern and in which the drain electrode contacts the drain region.

In an embodiment, the first barrier pattern may extend to the boundary between the channel region and the source region and block hydrogen diffusion from the interlayer insulating layer to the source region. The second barrier pattern may extend to the boundary between the channel region and the drain region and block hydrogen diffusion from the interlayer insulating layer to the drain region.

In the display device according to embodiments of the present disclosure, an active pattern including an oxide semiconductor may have a first groove and a second groove. A first barrier pattern and a second barrier pattern may be located in the first groove and the second groove, respectively. Accordingly, diffusion of hydrogen to a channel region of the active pattern through an interlayer insulating layer located on the active pattern including the oxide semiconductor may be prevented or reduced.

The display device may further include a barrier layer located on the active pattern, located under the first barrier pattern, the second barrier pattern, and a gate insulating layer, and including an inorganic material. The barrier layer may prevent or reduce damage to the active pattern which may occur when forming the first barrier pattern and the second barrier pattern.

The display device may prevent or reduce hydrogen from diffusing from the interlayer insulating layer by locating the first barrier pattern on the source region and the second barrier pattern on the drain region.

Accordingly, the reliability of the display device including the oxide semiconductor may be improved.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a plan view illustrating a display device according to an embodiment.

FIG. 2 is a cross-sectional view taken along line I-I′ of FIG. 1.

FIG. 3 is an enlarged cross-sectional view illustrating area A of FIG. 2.

FIGS. 4 to 15 are cross-sectional views illustrating an example of a method of providing (or manufacturing) the display device of FIGS. 2 and 3.

FIG. 16 is a cross-sectional view illustrating a display device according to an embodiment.

FIG. 17 is an enlarged cross-sectional view illustrating area B of FIG. 16.

FIGS. 18 to 21 are cross-sectional views illustrating an example of a method of providing (or manufacturing) the display device of FIGS. 16 and 17.

FIG. 22 is a cross-sectional view illustrating a display device according to an embodiment.

FIG. 23 is an enlarged cross-sectional view illustrating area C of FIG. 22.

FIGS. 24 to 30 are cross-sectional views illustrating an example of a method of providing (or manufacturing) the display device of FIGS. 22 and 23.

FIG. 31 is a block diagram illustrating an electronic device according to an embodiment.

FIG. 32 is a diagram illustrating an example in which the electronic device of FIG. 31 is implemented as a television.

FIG. 33 is a diagram illustrating an example in which the electronic device of FIG. 31 is implemented as a smartphone.

### DETAILED DESCRIPTION

Hereinafter, embodiments of the present disclosure will be described in more detail with reference to the accompanying drawings. In the drawings, the same reference numerals are used for the same components in the drawings, and redundant descriptions of the same components will be omitted.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In the present disclosure, a plane may be defined by a first direction DR1 and a second direction DR2 which intersects the first direction DR1. For example, the first direction DR1 and the second direction DR2 may be perpendicular to each other. A display device DD, various components, or layers may have a thickness extending along a third direction DR3 intersecting the plane, such as to define a thickness direction along the third direction DR3. In other words, the third direction DR3 may be perpendicular to each of the first direction DR1 and the second direction DR2.

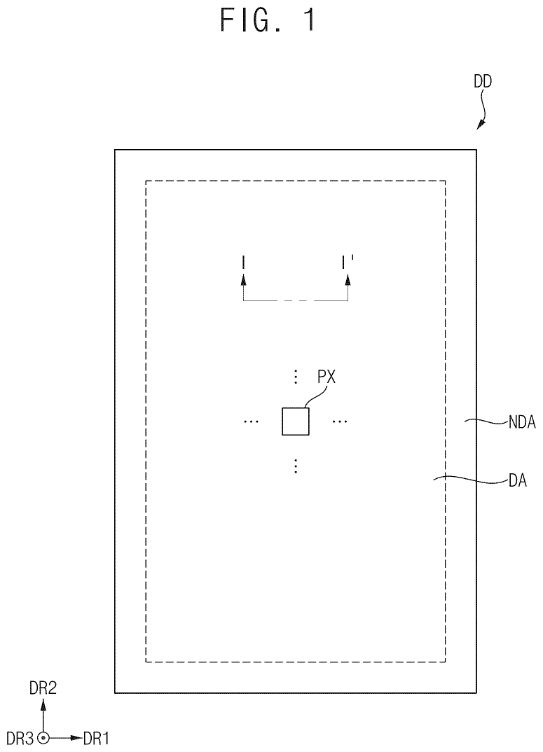

FIG. 1 is a plan view illustrating a display device DD according to an embodiment.

Referring to FIG. 1, a display device DD may be a device which is activated according to an electrical signal. For example, the display device DD may be a mobile phone, a tablet, or a wearable device, but the present disclosure is not limited thereto.

The display device DD may include a display area DA and a peripheral area NDA. The display area DA may be an area (e.g., a planar area) at which light is generated or an image is displayed by adjusting the transmittance of light provided from an external light source. The peripheral area NDA may be adjacent to the display area DA, such as to be located extending along or around the display area DA. For example, the peripheral area NDA may surround at least a portion of the display area DA in a plan view. In an embodiment, the peripheral area NDA may be an area at which an image is not displayed. However, the present disclosure is not limited thereto, and an image may be displayed in at least portion of the peripheral area NDA.

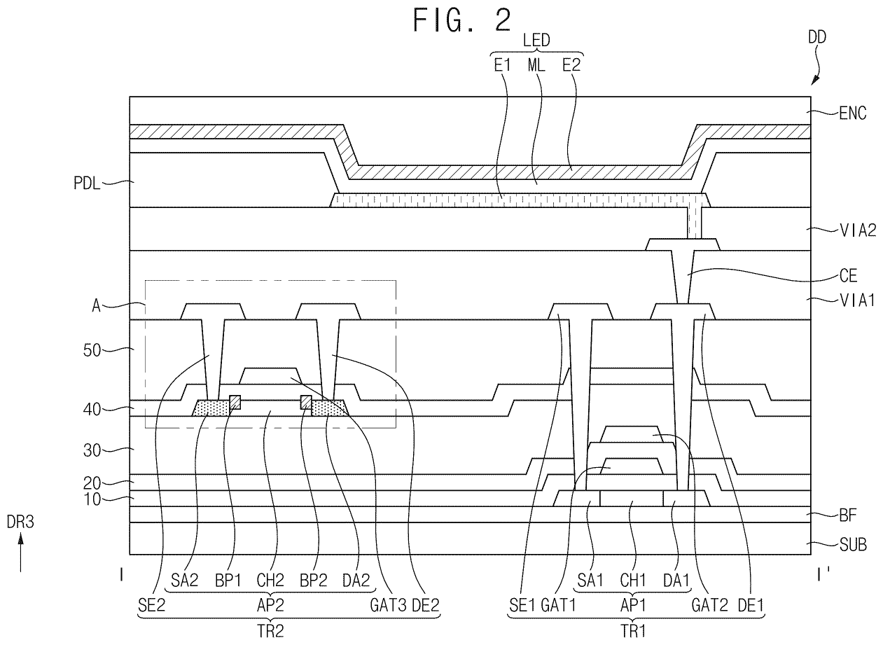

The display device DD may include a pixel PX. The pixel PX may be located in the display area DA, on a substrate (e.g., a substrate SUB of FIG. 2). The pixel PX may be electrically connected to a gate line, a data line, and a power line. For example, a plurality of pixels PX may be located in a matrix form along the first direction DR1 and the second direction DR2. The pixel PX may include a pixel driving circuit and a light emitting element LED which is connected (e.g., physically, electrically, etc.) to the pixel driving circuit. The light emitting element may emit light. The light emitting element LED may be an organic light emitting diode or an inorganic light emitting diode. Detailed descriptions of the light emitting element LED will be described later with reference to FIG. 2.

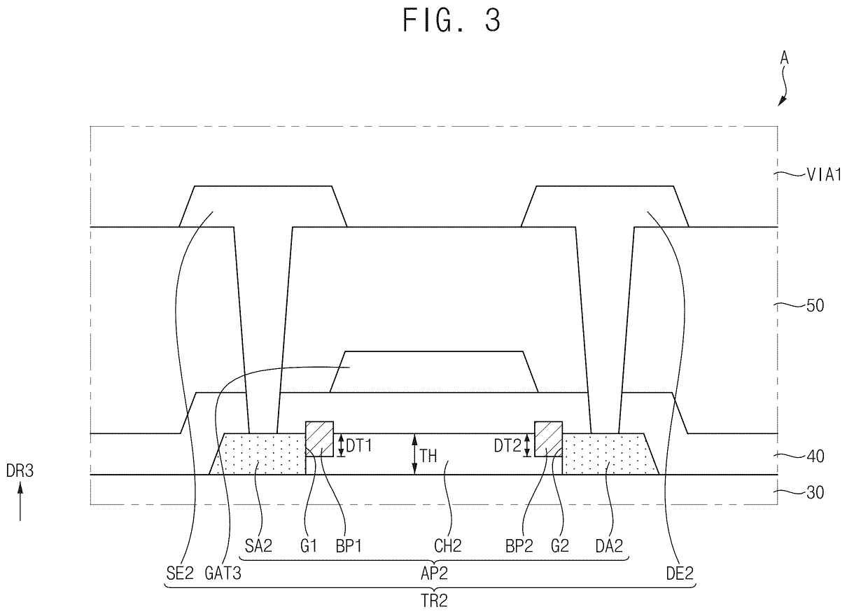

FIG. 2 is a cross-sectional view taken along line I-I′ of FIG. 1. FIG. 3 is an enlarged cross-sectional view illustrating area A of FIG. 2.

Referring to FIGS. 2 and 3, the display device DD according to an embodiment of the present disclosure may include a substrate SUB, a buffer layer BF, a first transistor TR1, a second transistor TR2, first to fifth insulating layers 10, 20, 30, 40, and 50, first and second organic insulating layers VIA1 and VIA2, a connection electrode CE, a pixel defining layer PDL, a light emitting element LED, and an encapsulation layer ENC.

In an embodiment, the substrate SUB may include glass, quartz, silicon, plastic, or the like. Examples of the plastic which can be used for the substrate SUB may include polyimide (PI), polyethylene terephthalate (PET), polyethylene naphthalene (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polyphenylene oxide (MPPO), or the like. These can be used alone or in combination with each other.

The buffer layer BF may be located on the substrate SUB. The buffer layer BF may prevent or reduce impurities, such as oxygen, moisture, or the like, from being diffused into an upper part of the substrate SUB, through the substrate SUB, and may planarize an upper surface of the substrate SUB. In an embodiment, the buffer layer BF may include an inorganic insulating material, such as a silicon compound, metal oxide, or the like. For example, the buffer layer BF may include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide(ZrOₓ), titanium oxide (TiOₓ), or the like. These can be used alone or in combination with each other. For example, the buffer layer BF may include silicon nitride. The buffer layer BF may have a single-layer structure or a multi-layer structure including a plurality of insulating layers arranged along the thickness direction.

The first transistor TR1 may be located on the buffer layer BF. The first transistor TR1 may include a first active pattern AP1, a first gate electrode GAT1, a first source electrode SE1, and a first drain electrode DE1. In an embodiment, the first transistor TR1 may be a driving transistor, but the present disclosure is not limited thereto.

The first active pattern AP1 may be located on the buffer layer BF. The first active pattern AP1 may include a first source region SA1, a first drain region DA1, and a first channel region CH1 between the first source region SA1 and the first drain region DA1. The first active pattern AP1 may include an oxide semiconductor, a silicon semiconductor, an organic semiconductor, or the like. In an embodiment, the first active pattern AP1 may include polycrystalline silicon. To form the first active pattern AP1, an amorphous silicon material layer may be formed (or provided) and then the amorphous silicon material layer may be crystallized to form a polycrystalline silicon layer.

For example, the amorphous silicon layer may be formed by sputtering, low-pressure chemical vapor deposition (LPCVD), plasma-enhanced chemical vapor deposition (PECVD), or the like. The amorphous silicon layer may be crystallized by excimer laser annealing (ELA), sequential lateral solidification (SLS), or the like.

For example, the polycrystalline silicon layer may be polished by chemical mechanical polishing (CMP), or the like to planarize a surface, and may be patterned by photolithography, or the like to form the first active pattern AP1.

The first insulating layer 10 may be located on the buffer layer BF and may cover the first active pattern AP1. The first insulating layer 10 may insulate the first channel region CH1 of the first active pattern AP1 and the first gate electrode GAT1 located on the first insulating layer 10. The first insulating layer 10 may include an inorganic insulating material. The first insulating layer 10 may protect the amorphous silicon from external contamination in a crystallization process of the amorphous silicon, and may also protect the polycrystalline silicon from being directly exposed to photoresist or external environment in a subsequent patterning process. For example, the first insulating layer 10 may be referred to as a first gate insulating layer.

The first gate electrode GAT1 may be located on the first insulating layer 10 and the first active pattern AP1 and may overlap the first channel region CH1. In an embodiment, the first gate electrode GAT1 may include a conductive material, such as metal, metal alloy, conductive metal nitride, conductive metal oxide, transparent conductive material, or the like. For example, the first gate electrode GAT1 may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride(TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These can be used alone or in combination with each other. The first gate electrode GAT1 may have a single-layer structure or a multi-layer structure including a plurality of conductive layers.

The second insulating layer 20 covering the first gate electrode GAT1 may be located on the first insulating layer 10. The second insulating layer 20 may include an inorganic insulating material. For example, the second insulating layer 20 may be referred to as a second gate insulating layer.

A second gate line pattern GAT2 may be located on the second insulating layer 20. At least a portion of the second gate line pattern GAT2 may overlap the first gate electrode GAT1 or the first active pattern AP1. In an embodiment, the second gate line pattern GAT2 may include or be a portion of a data signal line providing a data signal, a gate signal line providing a gate signal, an initialization signal line providing an initialization signal, a light emitting signal line providing a light emitting signal, a power voltage line providing a power voltage, or the like. In an embodiment, the first gate electrode GAT1 and the second gate line pattern GAT2 may form a capacitor. As being a portion of a respective signal line (like the data signal line, the gate signal line, the initialization signal line, etc., the second gate line pattern GAT2 and such signal line may be respective parts of a same single body of a conductive material layer.

The third insulating layer 30 covering the second gate line pattern GAT2 may be located on the second insulating layer 20. The third insulating layer 30 may include an inorganic insulating material. For example, the third insulating layer 30 may be referred to as a first interlayer insulating layer.

The second transistor TR2 may be located on the third insulating layer 30. The second transistor TR2 may include a second active pattern AP2, a third gate electrode GAT3, a second source electrode SE2, and a second drain electrode DE2. In an embodiment, the second transistor TR2 may be a switching transistor, but the present disclosure is not limited thereto.

The second active pattern AP2 may include a second source region SA2, a second drain region DA2, and a second channel region CH2 between the second source region SA2 and the second drain region DA2. The second active pattern AP2 may have (or define) a first groove G1 defined between the second source region SA2 and the second channel region CH2, and a second groove G2 between the second drain region DA2 and the second channel region CH2 in a direction along the second active pattern AP2. The first groove G1 and the second groove G2 may be open upward, in a direction away from the substate SUB. A first barrier pattern BP1 may be located in the first groove G1, and a second barrier pattern BP2 may be located in the second groove G2.

The second active pattern AP2 may be located on the third insulating layer 30, and may include an oxide semiconductor. In an embodiment, the second active pattern AP2 may include a binary compound (ABₓ), a ternary compound (ABₓC_{y}), a quaternary compound (ABₓC_{y}D_{z}), or the like containing indium (In), zinc (Zn), gallium (Ga), tin (Sn), titanium (Ti), aluminum (Al), hafnium (Hf), zirconium (Zr), magnesium (Mg), or the like. For example, the second active pattern AP2 may include zinc oxide (ZnOₓ), gallium oxide (GaOₓ), titanium oxide (TiOₓ), tin oxide (SnOₓ), indium oxide (InOₓ), indium gallium oxide (IGO), indium zinc oxide (IZO), indium tin oxide (ITO), gallium zinc oxide (GZO), zinc magnesium oxide (ZMO), zinc tin oxide (ZTO), zinc zirconium oxide (ZnZrOₓ), indium gallium zinc oxide (IGZO), indium zinc tin oxide (IZTO), indium gallium hafnium oxide (IGHO), tin aluminum zinc oxide (TAZO), indium gallium tin oxide (IGTO), or the like.

The first barrier pattern BP1 may contact the second active pattern AP2, and the second barrier pattern BP2 may contact the second active pattern AP2. In an embodiment, the first barrier pattern BP1 may contact the second source region SA2 of the second active pattern AP2, and the second barrier pattern BP2 may contact the second drain region DA2 of the second active pattern AP2, at opposing ends of the second channel region CH2. In an embodiment, the first barrier pattern BP1 may contact a portion of a side surface of the second source region SA2 which defines the first groove G1, and the second barrier pattern BP2 may contact a portion of a side surface of the second drain region DA2 which defines the second groove G2. Each of the first barrier pattern BP1 and the second barrier pattern BP2 contacts surfaces of the second channel region CH2 which define the respective grooves.

In an embodiment, the first barrier pattern BP1 and the second barrier pattern BP2 may be located between the fourth insulating layer 40 and the second active pattern AP2. A respective barrier pattern may extend out of a groove, and further than an upper surface of the second active pattern AP2 to define an extended portion of the respective barrier pattern. The extended portion may extend into the forth insulating layer 40, such that thickness portions of the respective barrier portion overlaps thicknesses of the second active pattern AP2 and the fourth insulating layer 40, respectively.

In an embodiment, a first depth DT1 of the first groove G1 may be less than a thickness TH (e.g., a total thickness) of the second active pattern AP2, and a second depth DT2 of the second groove G2 may be less than the thickness TH of the second active pattern AP2.

The first barrier pattern BP1 and the second barrier pattern BP2 may include a material preventing or reducing diffusion of hydrogen. In an embodiment, the first barrier pattern BP1 and the second barrier pattern BP2 may include metal. In an embodiment, the metal may include titanium (Ti), copper(Cu), or the like. These can be used alone or in combination with each other. That is, each of the first barrier pattern BP1 and the second barrier pattern BP2 may include at least one selected from titanium and copper.

The fourth insulating layer 40 and the fifth insulating layer 50 may be formed by depositing silicon oxide (SiOₓ), silicon nitride (SiNₓ), or the like using a plasma-enhanced chemical vapor deposition (PECVD) method, or the like. At this time, hydrogen contained in silicon oxide (SiOₓ), silicon nitride (SiNₓ), or the like may be diffused through deposition and heat treatment processes. When hydrogen is diffused from the fifth insulating layer 50 and the fourth insulating layer 40 to the second active pattern AP2, a physical length of the second channel region CH2 which is previously-formed, may be shortened. However, in high-resolution display devices, there is a limit to securing the length of the channel due to the increase in the density between lines (e.g., conductive lines, signal lines, etc.). Additionally, a short circuit may occur due to the shorter length of the channel, resulting in a reliability problem of the display device DD.

The first barrier pattern BP1 may prevent or reduce hydrogen from diffusing from the second source region SA2 to the second channel region CH2, and the second barrier pattern BP2 may prevent or reduce hydrogen from diffusing from the second drain region DA2 to the second channel region CH2, where such hydrogen is provided in subsequently forming an overlying layer like the fourth insulating layer 40 and/or the fifth insulating layer 50. The barrier patterns may be disposed in a barrier pattern layer, and may be otherwise referred to as a hydrogen-barrier pattern or layer. Accordingly, the reliability of the display device DD may be improved by maintaining the length of the second channel region CH2, and the high-resolution display device DD may be manufactured.

The fourth insulating layer 40 covering the second active pattern AP2, the first barrier pattern BP1, and the second barrier pattern BP2 may be located on the third insulating layer 30. The fourth insulating layer 40 may insulate the second channel region CH2 of the second active pattern AP2 and the third gate electrode GAT3 located on the fourth insulating layer 40. The fourth insulating layer 40 may include an inorganic insulating material. For example, the fourth insulating layer 40 may be referred to as a third gate insulating layer.

In an embodiment, for example, a transistor is on the substrate SUB and includes an active pattern including an oxide semiconductor and in which grooves are defined. Among the grooves, a first groove G1 is between the source region and the channel region, and a second groove G2 is between the drain region and the channel region. a barrier pattern layer is on the active pattern and includes a first barrier pattern BP1 in the first groove G1 of the active pattern and a second barrier pattern BP2 in the second groove G2 of the active pattern. The barrier pattern layer may include a hydrogen-blocking material, the first barrier pattern BP1 which is in the first groove G1 may block hydrogen diffusion from the gate insulating layer (e.g., the fourth insulating layer 40) to the channel region via the source region, and the second barrier pattern BP2 which is in the second groove G2 may block hydrogen diffusion from the gate insulating layer to the channel region via the drain region.

The third gate electrode GAT3 may be located on the fourth insulating layer 40 and the second active pattern AP2, and may overlap the second channel region CH2. The third gate electrode GAT3 may include a conductive material.

The fifth insulating layer 50 covering the third gate electrode GAT3 may be located on the fourth insulating layer 40. The fifth insulating layer 50 may include an organic and/or inorganic insulating material. For example, the fifth insulating layer 50 may be referred to as a second interlayer insulating layer. One or more of the first to fifth insulating layers 10 to 50 may be referred to as ‘an insulating layer’.

The first source electrode SE1, the first drain electrode DE1, the second source electrode SE2, and the second drain electrode DE2 may be located on the fifth insulating layer 50. The first source electrode SE1 and the first drain electrode DE1 may contact the first source region SA1 and the first drain region DA1 of the first active pattern AP1 through contact holes, respectively, which are defined extended completely through a thickness of a respective insulating layer. The second source electrode SE2 and the second drain electrode DE2 may contact the second source region SA2 and the second drain region DA2 of the second active pattern AP2 through contact holes, respectively.

The first organic insulating layer VIA1 covering the electrodes SE1, DE1, SE2, and DE2 may be located on the fifth insulating layer 50. The first organic insulating layer VIA1 may include an organic insulating material. For example, the first organic insulating layer VIA1 may include photoresist, polyacryl-based resin, polyimide-based resin, polyamide-based resin, siloxane-based resin, acryl-based resin, epoxy-based resin, or the like. These can be used alone or in combination with each other. For example, the first organic insulating layer VIA1 may be referred to as a first via insulating layer.

The connection electrode CE may be located on the first organic insulating layer VIA1. The connection electrode CE may contact the first drain electrode DE1 through a contact hole.

The second organic insulating layer VIA2 covering the connection electrode CE may be located on the first organic insulating layer VIA1. The second organic insulating layer VIA2 may include an organic insulating material. For example, the second organic insulating layer VIA2 may be referred to as a second via insulating layer.

The light emitting element LED may be located on the second organic insulating layer VIA2. The light emitting element LED may include a first electrode E1, a middle layer ML, and a second electrode E2.

The first electrode E1 may be located on the second organic insulating layer VIA2. The first electrode E1 may include a conductive material. The first electrode E1 may be connected to the connection electrode CE through a contact hole formed in the second organic insulating layer VIA2. Accordingly, the first electrode E1 may be electrically connected to the first transistor TR1. For example, the first electrode E1 may function as an anode of the light emitting element LED.

The pixel defining layer PDL may be located on the first electrode E1. A solid (material) portion of the pixel defining layer PDL may cover a peripheral portion of the first electrode E1 and may define a pixel opening exposing a central portion of the first electrode E1 to outside the pixel defining layer PDL. A light emitting area may be defined by or correspond to the pixel opening. The pixel defining layer PDL may include an organic insulating material. In an embodiment, the pixel defining layer PDL may further include an inorganic or organic material containing a black-colored light blocking material.

The middle layer ML may be located on the first electrode E1 and the pixel defining layer PDL. A portion of the middle layer ML may be located in the pixel opening of the pixel defining layer PDL. In an embodiment, although not shown, the middle layer ML may include a first functional layer including an organic material, a light emitting layer located on the first functional layer and including a light emitting material, and a second functional layer located on the light emitting layer and including an organic material. For example, the first functional layer may include a hole injection layer, a hole transport layer, or the like, and the second functional layer may include an electron transport layer, an electron injection layer, or the like. In an embodiment, the middle layer ML may include a low molecular weight organic compound or a high molecular weight organic compound.

In an embodiment, the middle layer ML may emit red light, green light, or blue light. In an embodiment, when the middle layer ML emits white light, the middle layer ML may include a multi-layer structure including a red light emitting layer, a green light emitting layer, and a blue light emitting layer, or may include a single-layer structure including red light emitting materials, green light emitting materials, and blue light emitting materials. For example, the middle layer ML may be formed by screen printing, inkjet printing, deposition, or the like.

Referring to FIGS. 1 and 2, the second electrode E2 may be located on the middle layer ML. The second electrode E2 may continuously extend on the display area DA across the plurality of the pixels PX and may include a conductive material. For example, the second electrode E2 may function as a cathode of the light emitting element LED.

The encapsulation layer ENC may be located on the second electrode E2. The encapsulation layer ENC may include at least one inorganic encapsulation layer and at least one organic encapsulation layer.

In addition, although not shown in the drawing, various functional layers, such as a touch sensing layer, a color filter layer, a light collection layer, or the like, may be additionally located on the encapsulation layer ENC.

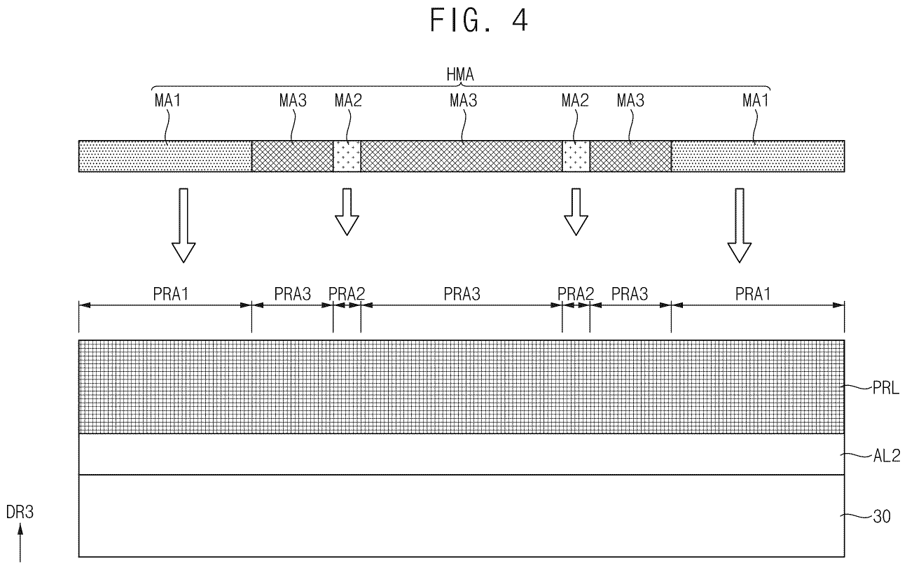

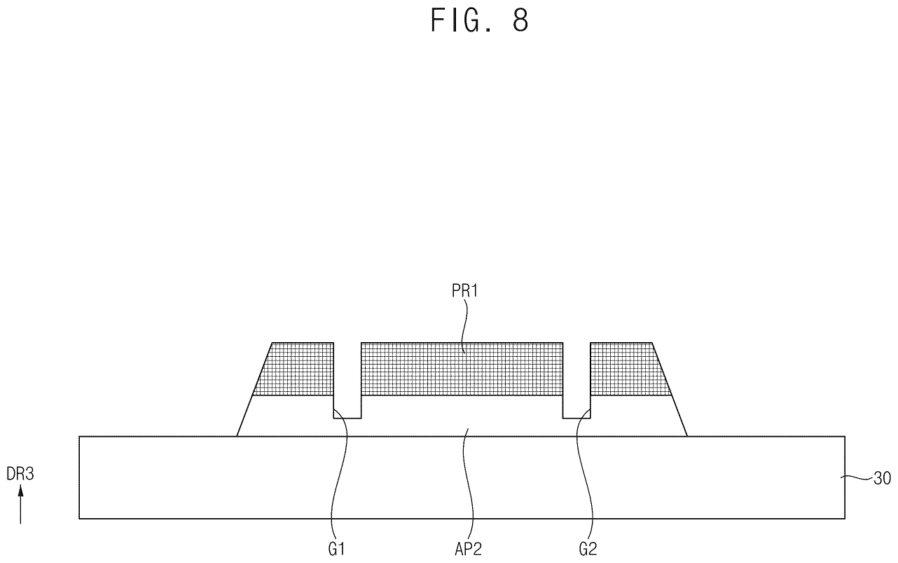

FIGS. 4 to 15 are cross-sectional views illustrating an example of a method of manufacturing (or providing) the display device DD of FIGS. 2 and 3.

Hereinafter, an example of a method of manufacturing the display device DD of FIGS. 2 and 3 will be described in detail with reference to FIGS. 4 to 15. FIGS. 4 to 15 mainly show a method of manufacturing the second transistor TR2 shown in FIG. 3.

First, as shown in FIG. 2, the buffer layer BF, the first active pattern AP1, the first insulating layer 10, the first gate electrode GAT1, the second insulating layer 20, the second gate line pattern GAT2, and the third insulating layer 30 may be sequentially formed (or provided) on the substrate SUB.

Referring to FIG. 4, an active layer AL2 including an oxide semiconductor may be formed on the third insulating layer 30, and a photoresist layer PRL may be formed on the active layer AL2. The active layer AL2 may be a preliminary active layer. The photoresist layer PRL may include a binder resin, such as phenol-based resin, acrylic resin, or the like.

A mask with a predetermined pattern may be used to pattern the photoresist layer PRL. The mask may include a halftone mask including a light transmitting area MA1, a semi-transmitting area MA2, and a light blocking area MA3. The light transmitting area MA1 of the halftone mask HMA may transmit the irradiated light, the semi-transmitting area MA2 of the halftone mask HMA may transmit only a portion of the irradiated light, and the light blocking area MA3 may block the irradiated light. The thickness of the arrow shown in FIG. 4 indicates the degree of light transmission where a larger thickness represents a larger light transmission of the mask area, and FIG. 4 is a conceptual diagram to conceptually explain the function of the halftone mask HMA. In this embodiment, the photoresist layer PRL may include a positive photoresist (positive PR) in which the exposed portion is removed by a developer, but the present disclosure is not limited thereto, and a negative photoresist (negative PR) may also be used.

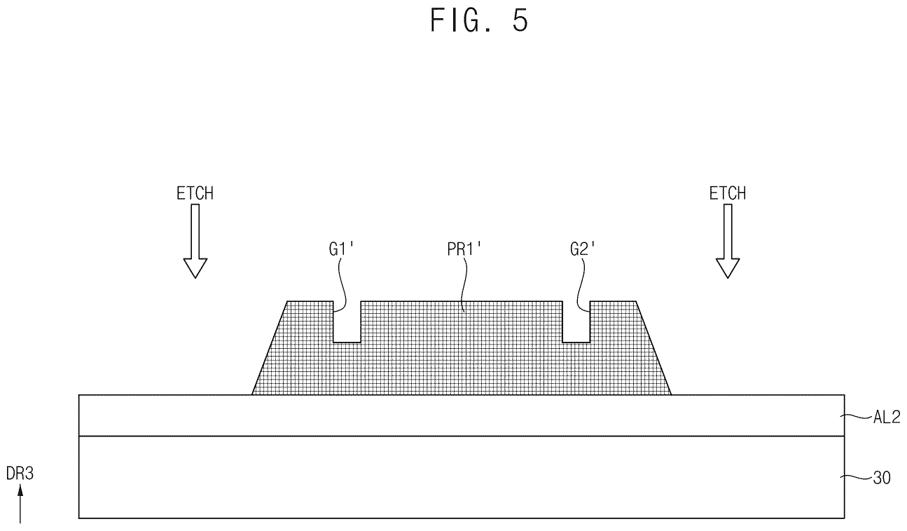

After aligning the halftone mask HMA on the photoresist layer PRL, an exposure process may be performed by irradiating light to the photoresist layer PRL, and then a development process may be performed to remove the exposed portion of the photoresist layer PRL. At this time, a total thickness of the photoresist layer PRL at a first photoresist area PRA1 corresponding to the light transmitting area MA1 of the halftone mask HMA may be removed, the photoresist layer PRL at a second photoresist area PRA2 corresponding to the semi-transmitting area MA2 may be partially removed depending on the amount of light exposure, and no thickness of the photoresist layer PRL at a third photoresist area PRA3 corresponding to the light blocking area MA3 may be removed. As a result of performing the above process, a preliminary photoresist pattern PR1′ of FIG. 5 may be formed. However, the present disclosure is not limited thereto, and any process commonly used to form grooves in the active layer may be used.

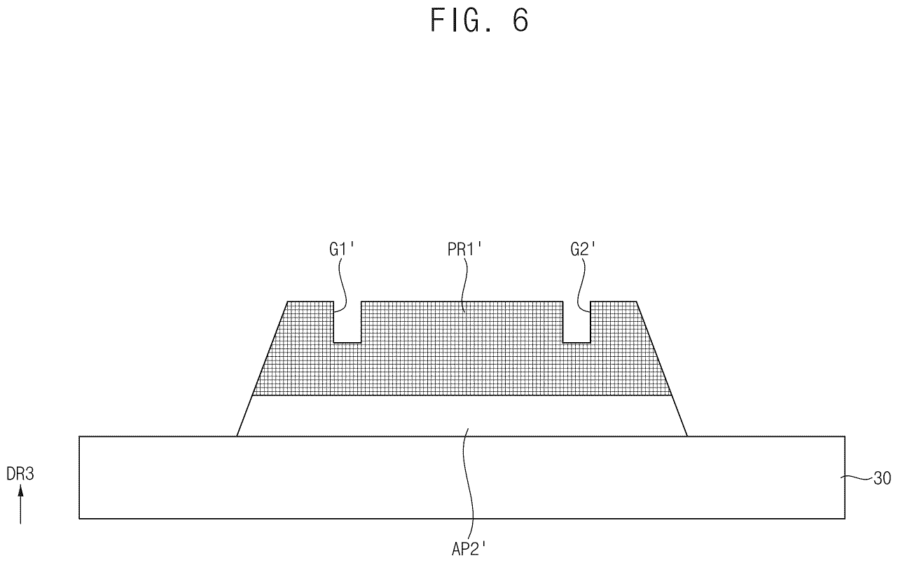

Referring to FIGS. 5 and 6, the preliminary photoresist pattern PR1′ may include a first preliminary groove G1′ and a second preliminary groove G2′ which are formed by the semi-transmitting area MA2 of the halftone mask HMA and respectively correspond to the first groove G1 and the second groove G2. Additionally, the exposed active layer AL2 may be etched using the preliminary photoresist pattern PR1′ as an etch mask to form a second preliminary active pattern AP2′. At this time, the etching process may be performed by various methods, such as wet etching, dry etching, or the like. For example, the active layer AL2 may be etched by dry etching using plasma, or the like. As the second preliminary active pattern AP2′ is formed, the third insulating layer 30 around the second preliminary active pattern AP2′ may be exposed to outside the stacked structure of FIG. 6.

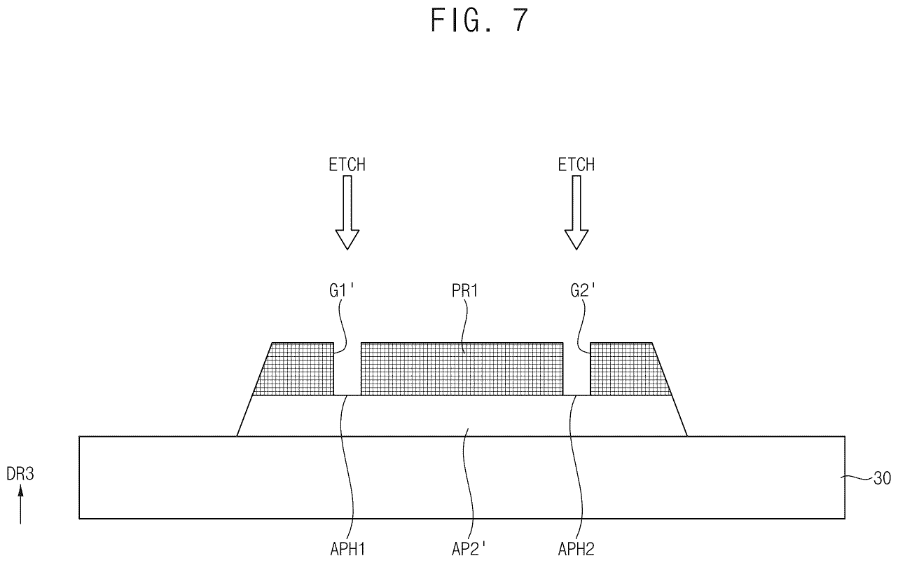

Referring to FIG. 7, the preliminary photoresist pattern PR1′ may be ashed until the first preliminary groove G1′ and the second preliminary groove G2′ of the preliminary photoresist pattern PR1′ expose some areas APH1 and APH2 of an upper surface of the second preliminary active pattern AP2′. As a result, a photoresist pattern PR1 may be formed and the second preliminary active pattern AP2′ may include exposed portions at areas APH1 and APH2.

Referring to FIG. 7and 8, the exposed second preliminary active pattern AP2′ may be etched using the photoresist pattern PR1 as an etch mask. The second preliminary active pattern AP2′ may be etched to remove only up to a certain point between an upper surface and a lower surface which is separated from the upper surface by the thickness of the second preliminary active pattern AP2′. Accordingly, the second active pattern AP2 having the first groove G1 and the second groove G2 may be formed. The depth of each of the first groove G1 and the second groove G2 which is taken from the upper surface of the second preliminary active pattern AP2′ may be less than the thickness (e.g., a total thickness) of the second active pattern AP2. That is, a thickness (material) portion of the second active pattern AP2 may remain under each of the grooves.

The grooves may correspond to a boundary between the channel region and a source (or drain) region which extends from the channel region. Referring to FIG. 3, for example, an edge of the groove may be aligned along the thickness direction with the boundary, and extend from the boundary and into the channel region in a planar direction along the second active pattern AP2.

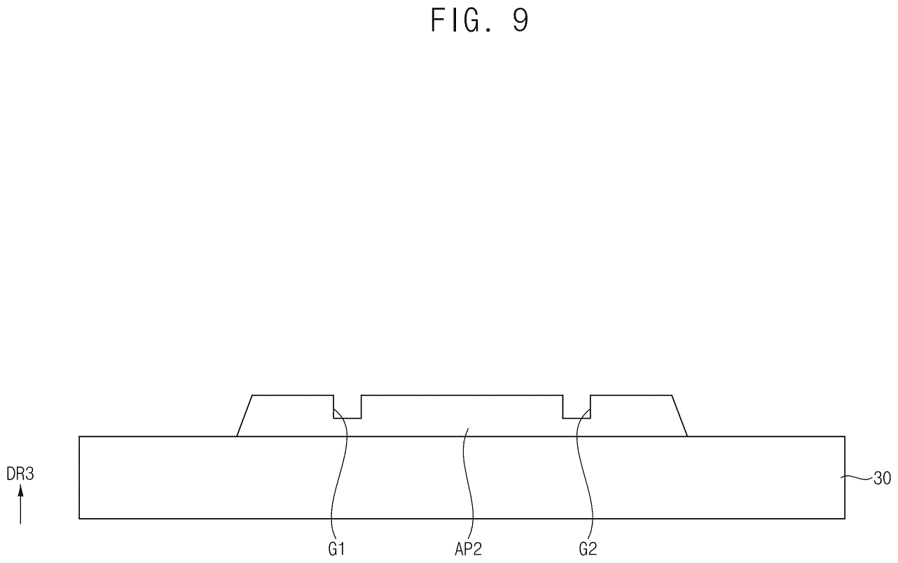

Referring to FIG. 9, after a shape (e.g., planar and cross-sectional) of the second active pattern AP2 is formed, the photoresist pattern PR1 may be removed.

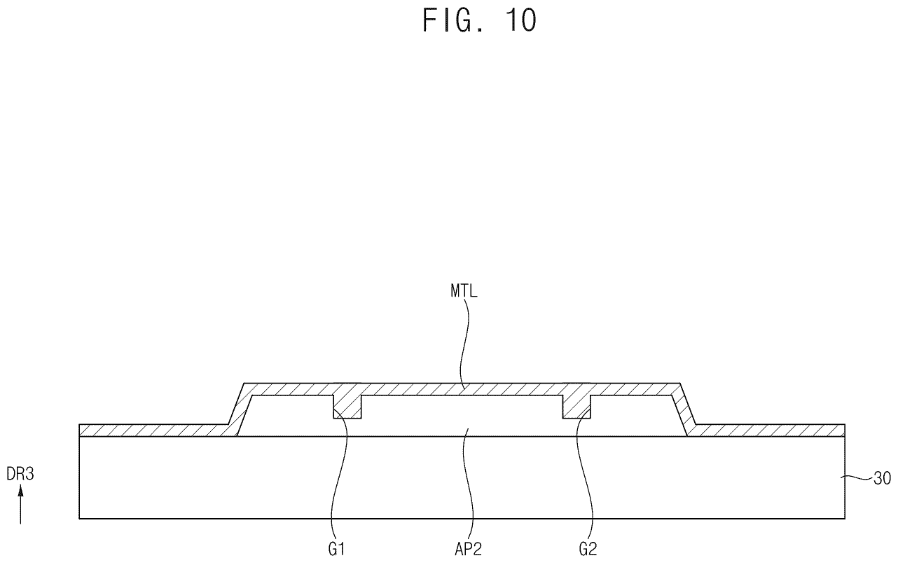

Referring to FIG. 10, a metal layer MTL as a metal material layer may be formed on the second active pattern AP2 and on an exposed portion of the third insulating layer 30. In an embodiment, the metal layer MTL may be formed using titanium (Ti), copper (Cu), or the like. In an embodiment, the metal layer MTL may be formed by a sputtering process. The metal material may extend into and fill the grooves defined in the second active pattern AP2.

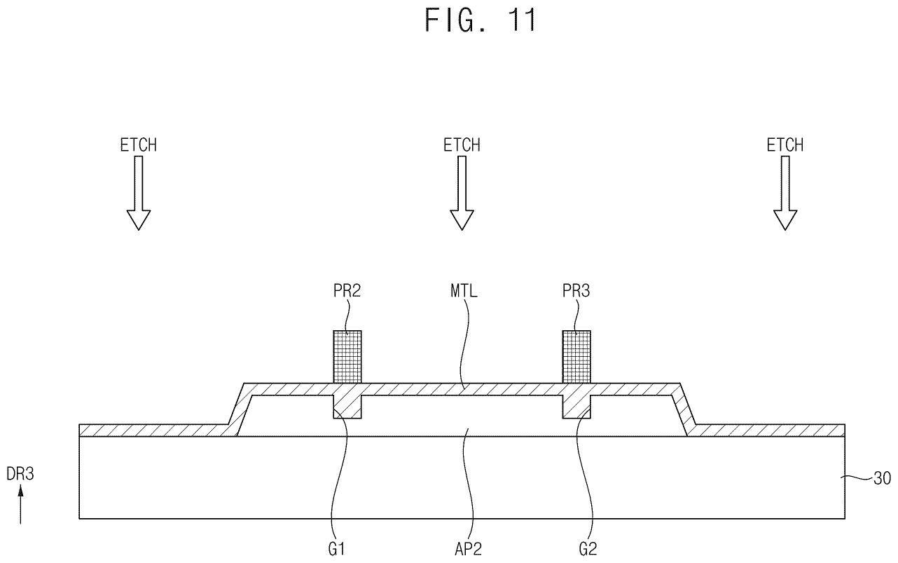

Referring to FIG. 11, a photoresist layer (not shown) may be formed on the metal layer MTL. The photoresist layer may be patterned to form photoresist patterns PR2 and PR3 overlapping the first groove G1 and the second groove G2 of the second active pattern AP2, respectively, on the metal layer MTL.

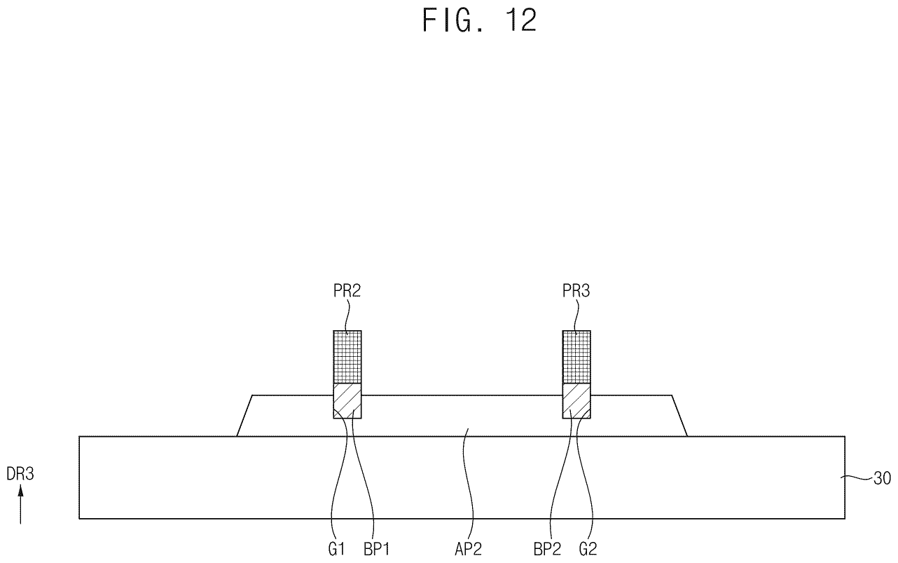

Referring to FIGS. 11 and 12, the exposed metal layer MTL may be etched using the photoresist patterns PR2 and PR3 as an etch mask. Material portions of the metal layer MTL may be removed, except for portions corresponding to the grooves. As a result, the first barrier pattern BP1 and the second barrier pattern BP2 overlapping the first groove G1 and the second groove G2 of the second active pattern AP2, respectively, may be formed. At this time, the etching process may be performed by various methods, such as wet etching, dry etching, or the like. The first barrier pattern BP1 and the second barrier pattern BP2 may be in a same layer as each other. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

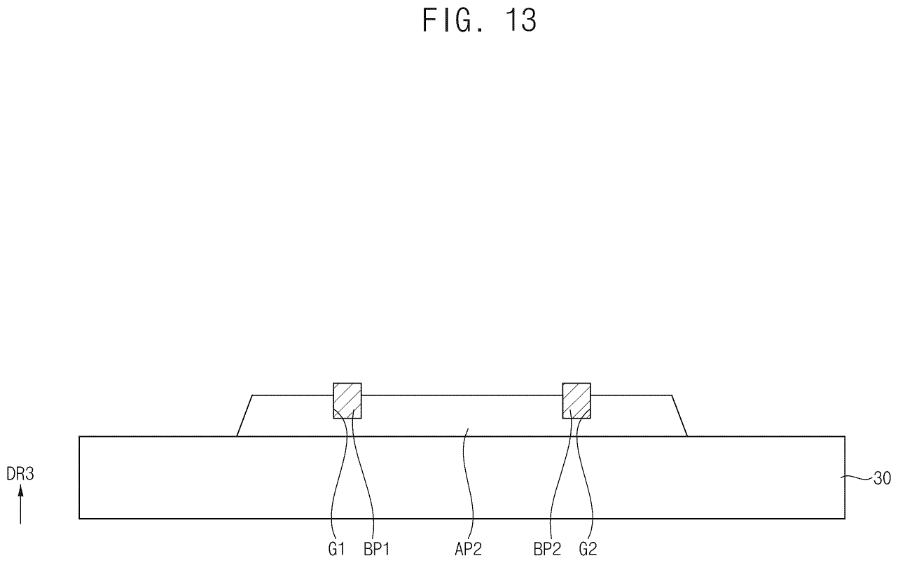

Referring to FIG. 13, after the first barrier pattern BP1 and the second barrier pattern BP2 are formed, the photoresist patterns PR2 and PR3 may be removed.

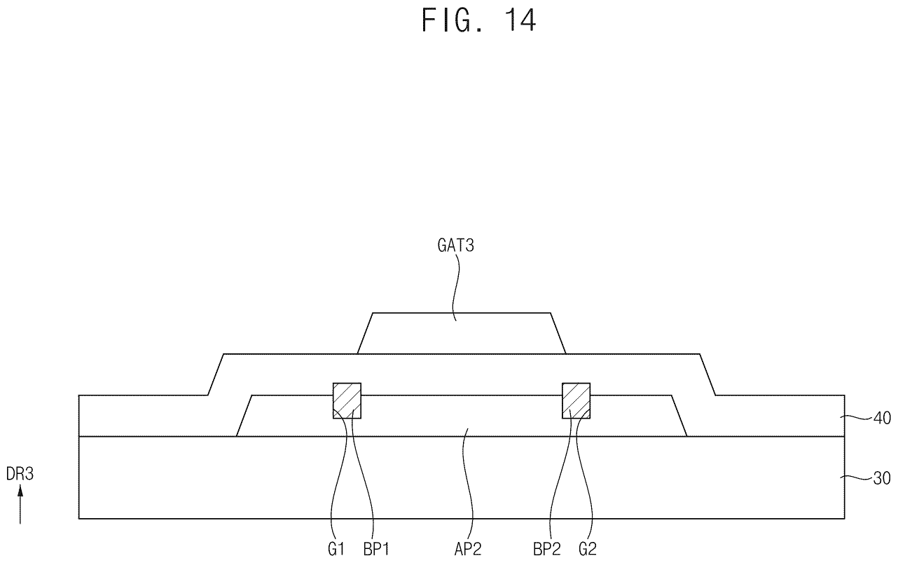

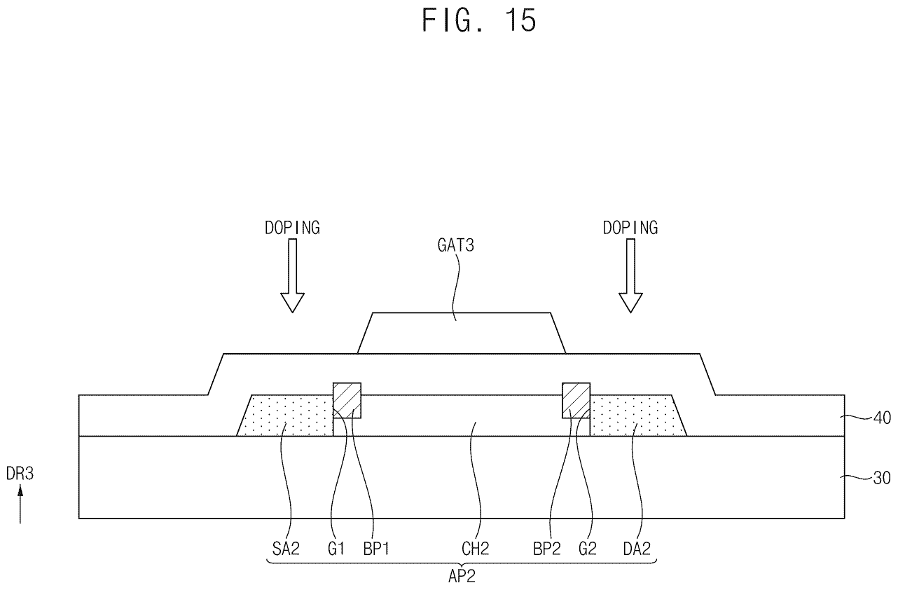

Referring to FIGS. 14 and 15, the hydrogen-barrier patterns may be provided at the boundary between the channel region and a source (or drain) region, before a process which involves hydrogen, such as a process for providing the fourth insulating layer 40. In an embodiment, the fourth insulating layer 40 may be formed on the second active pattern AP2, the first barrier pattern BP1, and the second barrier pattern BP2, and a metal layer (not shown) may be formed on the fourth insulating layer 40. A photoresist pattern may be formed on the metal layer, and the metal layer may be patterned using the photoresist pattern as a mask. Accordingly, the third gate electrode GAT3 may be formed.

A peripheral portion of the second active pattern AP2 which is adjacent to or extended from a channel area may be doped with N-type impurities using the third gate electrode GAT3, the first barrier pattern BP1, and the second barrier pattern BP2 as a mask. Accordingly, the second source region SA2 and the second drain region DA2 may be formed. Here, the second active pattern AP2 shown in FIG. 14 may be an undoped material layer having the barrier patterns therein, while the second active pattern in FIG. 15 is a doped material layer having the barrier patterns therein, such as corresponding to or overlapping a boundary between the channel region and an adjacent region.

Subsequently, as shown in FIG. 2, the display device DD may be manufactured by sequentially forming the fifth insulating layer 50, the first and second source electrodes SE1 and SE2, the first and second drain electrodes DE1 and DE2, the first organic insulating layer VIA1, the connection electrode CE, the second organic insulating layer VIA2, the first electrode E1, the pixel defining layer PDL, the middle layer ML, and the second electrode E2 on the third gate electrode GAT3.

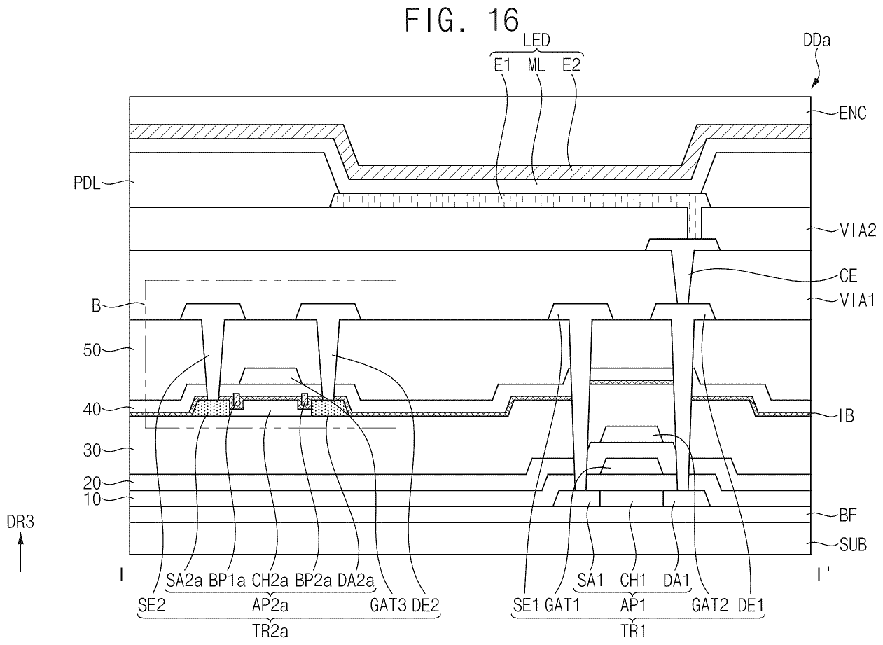

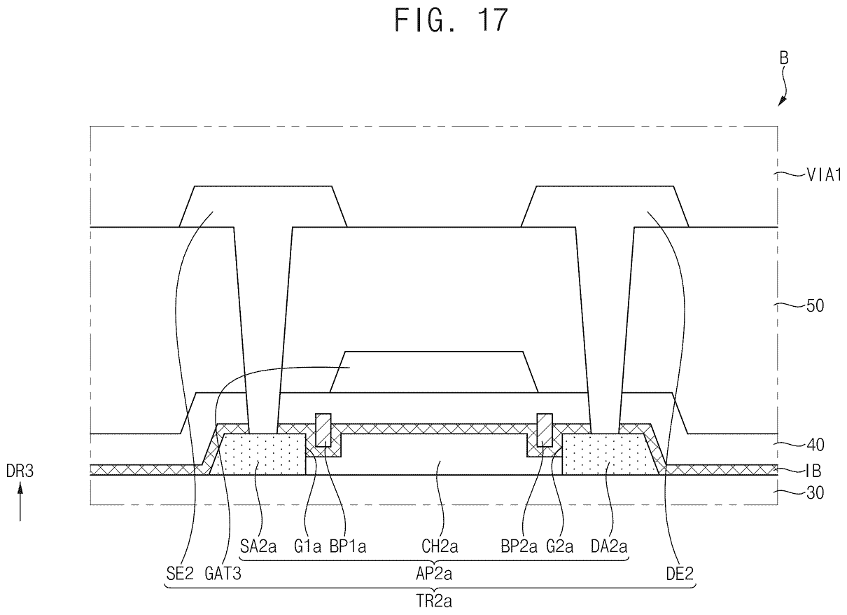

FIG. 16 is a cross-sectional view illustrating a display device according to an embodiment. FIG. 17 is an enlarged cross-sectional view illustrating an area B of FIG. 16.

A display device DDa of FIGS. 16 and 17 may be substantially the same as or similar to the display device DD of FIGS. 2 and 3 except that the display device DDa further includes a barrier layer IB. Therefore, overlapping descriptions will be omitted or simplified.

Referring to FIGS. 16 and 17, the display device DDa according to an embodiment of the present disclosure may further include the barrier layer IB located on the second active pattern AP2a.

The barrier layer IB may be located on the third insulating layer 30 and the second active pattern AP2a. In an embodiment, the barrier layer IB may entirely cover an upper surface and a side surface of the second active pattern AP2a, on the third insulating layer 30. In an embodiment, the barrier layer IB may be located along a profile of the upper surface and side surfaces of the second active pattern AP2a. a portion of the barrier layer IB may be located in the first groove G1a of the second active pattern AP2a, and another portion of the barrier layer IB may be located in the second groove G2a of the second active pattern AP2a.

In an embodiment, the barrier layer IB may include an inorganic insulating material, such as a silicon compound, metal oxide, or the like. For example, the barrier layer IB may include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or the like. These can be used alone or in combination with each other. For example, the barrier layer IB may include silicon nitride. The barrier layer IB may have a single-layer structure or a multi-layer structure including a plurality of insulating layers.

In an embodiment, the inorganic insulating material of the barrier layer IB may have a relatively low hydrogen content. Therefore, diffusion of hydrogen from the barrier layer IB to the second active pattern AP2a may be prevented or reduced.

The barrier layer IB may prevent or reduce damage to the second active pattern AP2a which may occur when forming the first barrier pattern BP1a and the second barrier pattern BP2a. That is, the barrier layer IB may serve to protect the second active pattern AP2a from being directly exposed to the photoresist or an external environment in the patterning process providing the barrier patterns.

The first barrier pattern BP1a and the second barrier pattern BP2a may be located on the barrier layer IB. That is, the barrier layer IB may be located under the first barrier pattern BP1a and the second barrier pattern BP2a. In other words, the barrier layer IB may be located between the second active pattern AP2a and the first barrier pattern BP1a and between the second active pattern AP2a and the second barrier pattern BP2a. The barrier layer IB may also be located between the third insulating layer 30 and the fourth insulating layer 40.

In an embodiment, the first barrier pattern BP1a may be located between the barrier layer IB and the fourth insulating layer 40 in the first groove G1a, and the second barrier pattern BP2a may be located between the barrier layer IB and the fourth insulating layer 40 in the second groove G2a.

The first barrier pattern BP1 and the second barrier pattern BP2 may include a material capable of preventing or reducing diffusion of hydrogen. In an embodiment, the first barrier pattern BP1a and the second barrier pattern BP2a may include metal. In an embodiment, the metal may include titanium (Ti), copper (Cu), or the like. These can be used alone or in combination with each other.

When hydrogen diffuses from materials forming the fifth insulating layer 50 and the fourth insulating layer 40 to the second active pattern AP2a, the physical length of the second channel region CH2a may be shortened. However, in high-resolution display devices, there is a limit to securing the length of the channel due to the increase in density between lines. Additionally, a short circuit may occur due to the shorter length of the channel, resulting in a reliability problem of the display device DDa.

The first barrier pattern BP1a may prevent or reduce hydrogen present or generated in forming an overlying layer from diffusing from the second source region SA2a to the second channel region CH2a, and the second barrier pattern BP2a may prevent or reduce hydrogen from diffusing from the second drain region DA2a to the second channel region CH2a. Therefore, the reliability of the display device DDa may be improved by maintaining the length of the second channel region CH2a, and the high-resolution display device DDa may be manufactured. Additionally, the barrier layer IB may cover the second active pattern AP2a and may prevent or reduce damage to the second active pattern AP2a which may occur when forming the first barrier pattern BP1a and the second barrier pattern BP2a. Accordingly, the reliability of the display device DDa may be further improved.

In an embodiment, for example, the barrier layer IB which includes an inorganic material layer is between the active pattern and the gate insulating layer (e.g., the fourth insulating layer 40), and is extended further than the active pattern in a direction along the substrate SUB (e.g., a direction parallel to the plane defined by the first direction DR1 and the second direction DR2 crossing each other). The barrier layer IB extends into the first groove G1a and the second groove G2a, the first barrier pattern BP1a is between the barrier layer IB and the gate insulating layer, in the first groove G1a, and the second barrier pattern BP2a is between the barrier layer IB and the gate insulating layer, in the second groove G2a. Here, the first barrier pattern BP1a which is in the first groove G1a may block hydrogen diffusion from the gate insulating layer to the channel region via the source region, and the second barrier pattern BP2a which is in the second groove G2a may block hydrogen diffusion from the gate insulating layer to the channel region via the drain region.

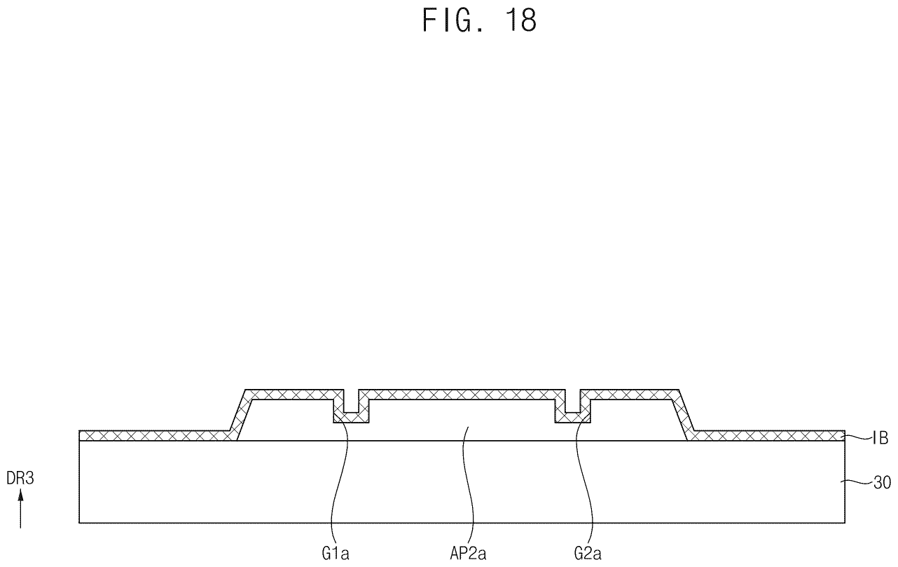

FIGS. 18 to 21 are cross-sectional views illustrating an example of a method of manufacturing the display device of FIGS. 16 and 17.

Hereinafter, an example of a method of manufacturing the display device DDa of FIGS. 16 and 17 will be described in detail with reference to FIGS. 18 to 21. FIGS. 18 to 21 mainly show a manufacturing method of the second transistor TR2a shown in FIG. 17.

First, as shown in FIG. 16, the buffer layer BF, the first active pattern AP1, the first insulating layer 10, the first gate electrode GAT1, the second insulating layer 20, the second gate line pattern GAT2, and the third insulating layer 30 may be sequentially formed on the substrate SUB.

Referring to FIG. 18, the second active pattern AP2a having the first groove G1a and the second groove G2a which are defined therein, may be formed on the third insulating layer 30. The second active pattern AP2a having the first groove G1a and the second groove G2a defined therein may be formed by the same manufacturing method as in FIGS. 4 to 9.

The barrier layer IB may be formed on the third insulating layer 30 and the second active pattern AP2a. In an embodiment, the barrier layer IB may be formed by depositing an inorganic insulating material, such as silicon oxide, silicon nitride, or the like, on the third insulating layer 30 and the second active pattern AP2a using a plasma-enhanced chemical vapor deposition (PECVD) method, or the like. However, the present disclosure is not limited thereto. The barrier layer IB is formed before the barrier patterns, to protect the second active pattern AP2a during operations providing the barrier patterns.

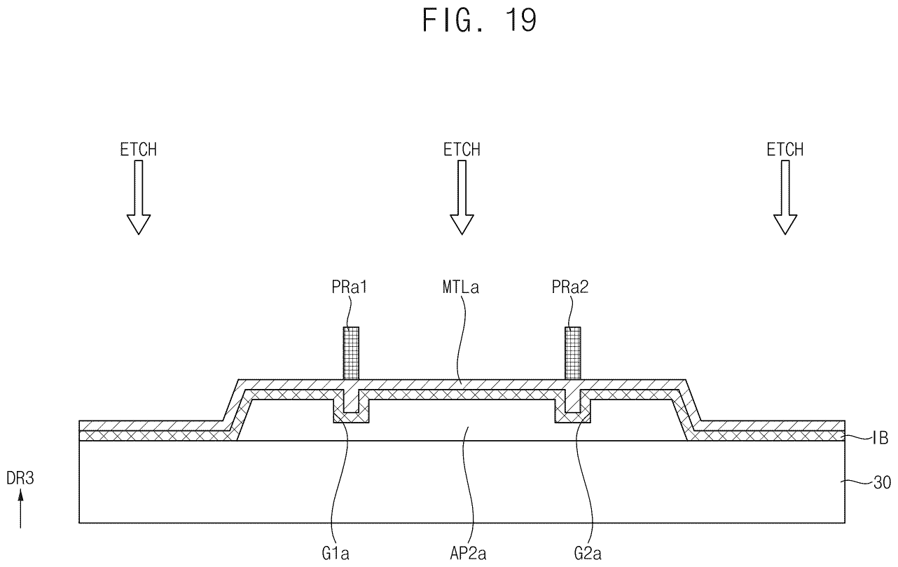

Referring to FIG. 19, a metal layer MTLa may be formed on the barrier layer IB. In an embodiment, the metal layer MTLa may be formed using titanium (Ti), copper (Cu), or the like. In an embodiment, the metal layer MTLa may be formed by a sputtering process.

A photoresist layer (not shown) may be formed on the metal layer MTLa. By patterning the photoresist layer, photoresist patterns PRa1 and PRa2 overlapping the first groove G1a and the second groove G2a of the second active pattern AP2a, respectively, may be formed on the metal layer MTLa.

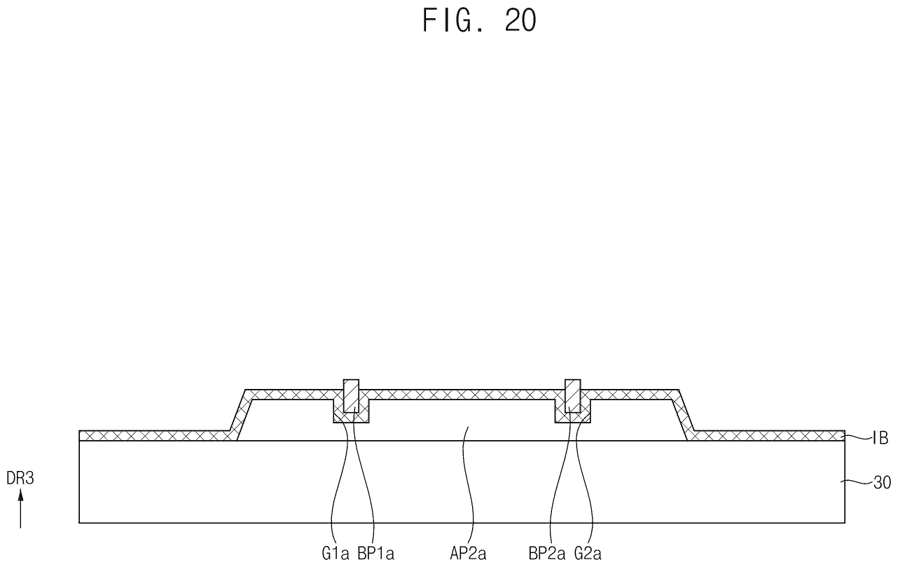

Referring to FIGS. 19 and 20, the exposed metal layer MTLa may be etched using the photoresist patterns PRa1 and PRa2 as an etch mask. As a result, the first barrier pattern BP1a and the second barrier pattern BP2a overlapping the first groove G1a and the second groove G2a of the second active pattern AP2a, respectively, may be formed. At this time, the etching process may be performed by various methods, such as wet etching, dry etching, or the like. After the first barrier pattern BP1a and the second barrier pattern BP2a are formed, the photoresist patterns PRa1 and PRa2 may be removed.

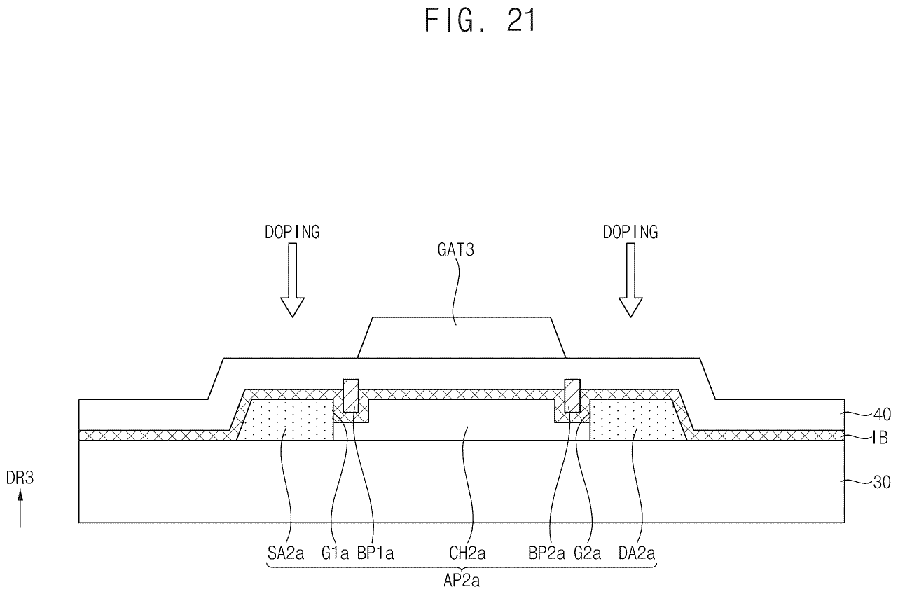

Referring to FIG. 21, the fourth insulating layer 40 may be formed on the barrier layer IB, the first barrier pattern BP1a, and the second barrier pattern BP2a, and a metal layer (not shown) may be formed on the fourth insulating layer 40. A photoresist pattern may be formed on the metal layer, and the metal layer may be patterned using the photoresist pattern as a mask. Accordingly, the third gate electrode GAT3 may be formed. Thereafter, a peripheral portion of the second active pattern AP2a may be doped with N-type impurities using the third gate electrode GAT3, the first barrier pattern BP1a, and the second barrier pattern BP2a as a mask. Accordingly, the second source region SA2a and the second drain region DA2a may be formed.

Subsequently, as shown in FIG. 16, the display device DDa may be manufactured by sequentially forming the fifth insulating layer 50, the first and the second source electrodes SE1 and SE2, the first and second drain electrodes DE1 and DE2, the first organic insulating layer VIA1, the connection electrode CE, the second organic insulating layer VIA2, the first electrode E1, the pixel defining layer PDL, the middle layer ML, and the second electrode E2 on the third gate electrode GAT3.

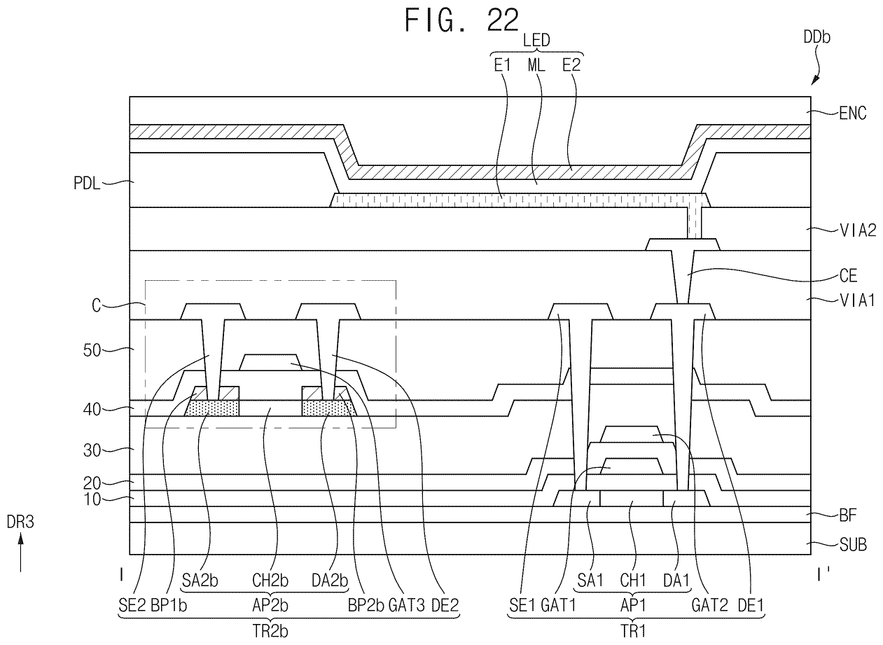

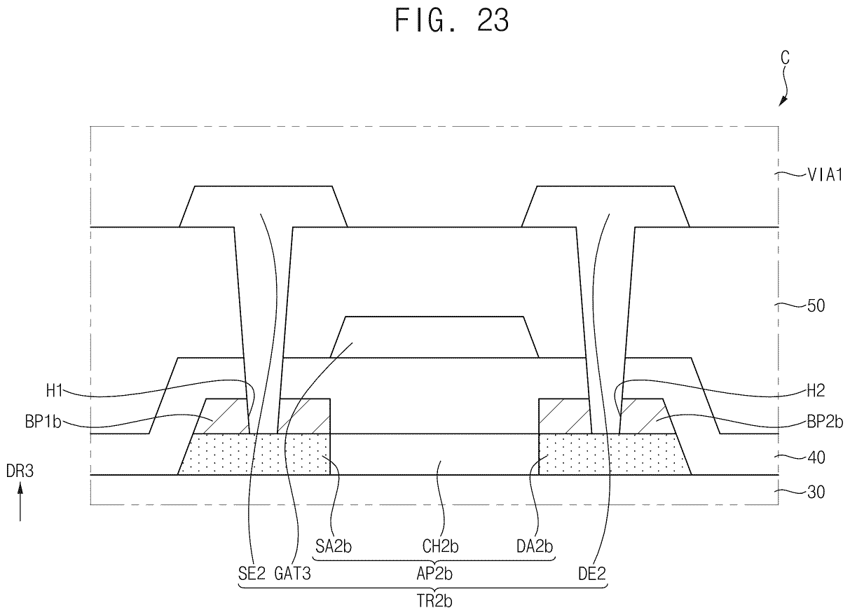

FIG. 22 is a cross-sectional view illustrating a display device DDb according to an embodiment. FIG. 23 is an enlarged cross-sectional view illustrating an area C of FIG. 22.

A display device DDb of FIGS. 22 and 23 may be substantially the same as or similar to the display device DD of FIGS. 2 and 3 except for the positions of the first barrier pattern BP1b and the second barrier pattern BP2b. Therefore, overlapping descriptions will be omitted or simplified.

Referring to FIGS. 22 and 23, in the display device DDb according to an embodiment of the present disclosure, the second active pattern AP2b may not have a groove between the second source region SA2b and the second channel region CH2b and between the second drain region DA2b and the second channel region CH2b.

An entirety of the thickness of the first barrier pattern BP1b may be located on the second source region SA2b of the second active pattern AP2b, and an entirety of the thickness of the second barrier pattern BP2b may be located on the second drain region DA2b of the second active pattern AP2b. In an embodiment, the first barrier pattern BP1b may contact the second active pattern AP2b, and the second barrier pattern BP2b may contact the second active pattern AP2b. For example, the first barrier pattern BP1b may be located on the second source region SA2b and may contact an upper surface of the second source region SA2b. The second barrier pattern BP2b may be located on the second drain region DA2b and may contact an upper surface of the second drain region DA2b.

In an embodiment, as shown in FIG. 22, the first barrier pattern BP1b may cover an entirety of the upper surface of the second source region SA2b of the second active pattern AP2b, and the second barrier pattern BP2b may cover an entirety of the upper surface of the second drain region DA2b of the second active pattern AP2b. In an embodiment, although not shown, the first barrier pattern BP1b may further cover a side surface (or end surface) of the second source region SA2b of the second active pattern AP2b, and the second barrier pattern BP2b may further cover a side surface (or end surface) of the second drain region DA2b of the second active pattern AP2b. Here, a barrier pattern may extend along an upper surface of the second active pattern AP2b and along outer side surfaces of the second active pattern AP2b at opposing ends thereof.

The first barrier pattern BP1b may have (or define) a first through hole H1 exposing a portion of the upper surface of the second source region SA2b. The first through hole H1 may penetrate the thickness of the first barrier pattern BP1b in the third direction DR3 (e.g., a thickness direction). The first through hole H1 may be an enclosed opening in a plan view, and may be spaced apart from outer edges of the first barrier pattern BP1b. The second source electrode SE2 may contact the upper surface of the second source region SA2b through the first through hole H1 of the first barrier pattern BP1b. As being in contact, elements may form an interface therebetween.

The second barrier pattern BP2b may have (or define) a second through hole H2 exposing a portion of the upper surface of the second drain region DA2b. The second through hole H2 may penetrate the thickness of the second barrier pattern BP2b in the third direction DR3. The second through hole H2 may be an enclosed opening in a plan view, and may be spaced apart from outer edges of the second barrier pattern BP2b. The second drain electrode DE2 may contact the upper surface of the second drain region DA2b through the second through hole H2 of the second barrier pattern BP2b. As being in contact, elements may form an interface therebetween.

The first barrier pattern BP1b and the second barrier pattern BP2b may include a material capable of preventing or reducing diffusion of hydrogen. In an embodiment, the first barrier pattern BP1b and the second barrier pattern BP2b may include metal. In an embodiment, the metal may include titanium (Ti), copper (Cu), or the like. These can be used alone or in combination with each other.

When hydrogen diffuses from the fifth insulating layer 50 and the fourth insulating layer 40 to the second active pattern AP2b, the physical length of the second channel region CH2b may be shortened. However, in high-resolution display devices, there is a limit to securing the channel length due to the increase in density between lines. Additionally, a short circuit may occur due to the shorter length of the channel, resulting in a reliability problem of the display device DDb.

The first barrier pattern BP1b may prevent or reduce hydrogen from diffusing from the fifth insulating layer 50 and fourth insulating layer 40 to the second source region SA2b, and the second barrier pattern BP2b may prevent or reduce hydrogen from diffusing from the fifth insulating layer 50 and the fourth insulating layer 40 to the second drain region DA2b. Accordingly, the reliability of the display device DDb may be improved by maintaining the length of the second channel region CH2b, and the high-resolution display device DDb may be manufactured.

In an embodiment, for example, a barrier pattern layer is on the active pattern and includes a first barrier pattern BP1b overlapping the source region of the active pattern, and a second barrier pattern BP2b overlapping the drain region of the active pattern. The first barrier pattern BP1b and the second barrier pattern BP2b contacts an upper surface of the active pattern at the source region and the drain region, respectively. The barrier patterns may include a first through hole defined through a thickness of the first barrier pattern BP1b, exposing the source region to outside the first barrier pattern BP1b and in which the source electrode contacts the source region, and a second through hole which is defined through a thickness of the second barrier pattern BP2b, exposing the drain region to outside the second barrier pattern BP2b and in which the drain electrode contacts the drain region. Referring to FIGS. 22 and 23, the first barrier pattern BP1b may extend to the boundary between the channel region and the source region and block hydrogen diffusion from the interlayer insulating layer (e.g., the fifth insulating layer 50) to the source region, and the second barrier pattern BP2b may extend to the boundary between the channel region and the drain region and block hydrogen diffusion from the interlayer insulating layer to the drain region.

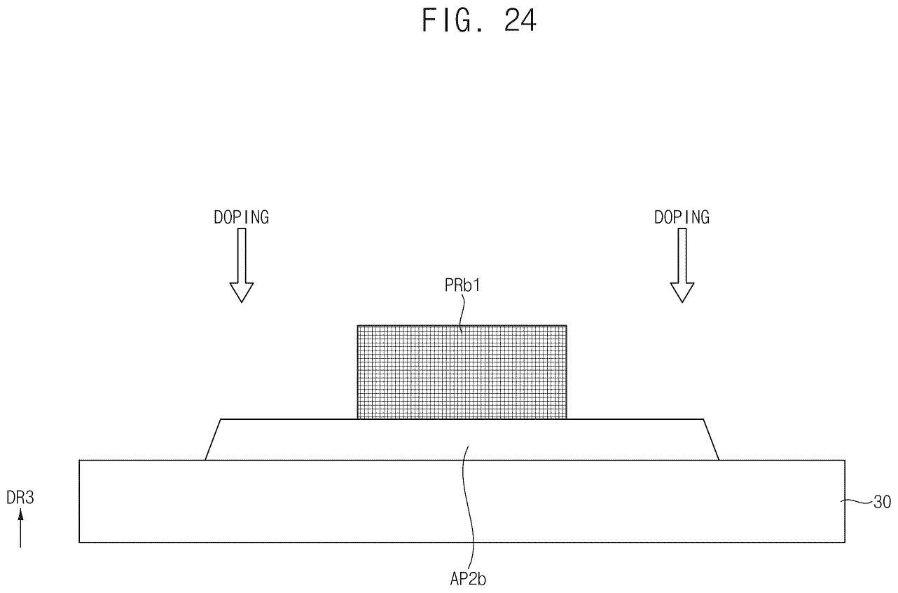

FIGS. 24 to 30 are cross-sectional views illustrating an example of a method of manufacturing the display device DDb of FIGS. 22 and 23.

Hereinafter, an example of a method of manufacturing the display device DDb of FIGS. 22 and 23 will be described in detail with reference to FIGS. 24 to 30. FIGS. 24 to 30 mainly show a method of manufacturing the second transistor TR2b shown in FIG. 23.

First, as shown in FIG. 22, the buffer layer BF, the first active pattern AP1, the first insulating layer 10, the first gate electrode GAT1, the second insulating layer 20, the second gate line pattern GAT2, and the third insulating layer 30 may be sequentially formed on the substrate SUB.

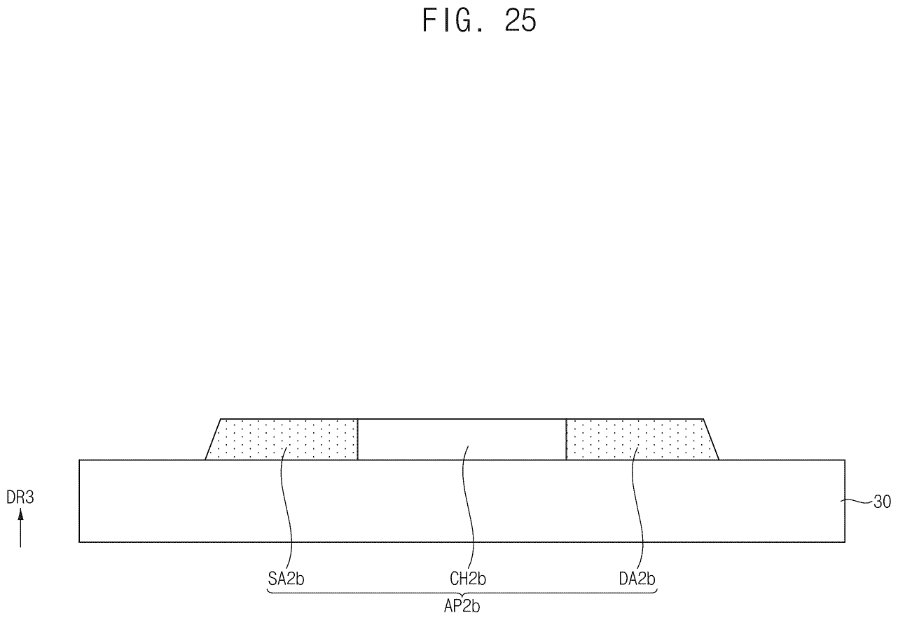

Referring to FIGS. 24 and 25, a photoresist pattern PRb1 may be formed on the second active pattern AP2b and may be used as a doping mask. In an embodiment, a peripheral portion of the second active pattern AP2b which does not overlap the photoresist pattern PRb1 may be doped with N-type impurities. As a result, the second source region SA2b and the second drain region DA2b may be formed. Thereafter, the photoresist pattern PRb1 may be removed. That is, the second active pattern AP2b as a doped material layer is provided before the providing of the barrier patterns.

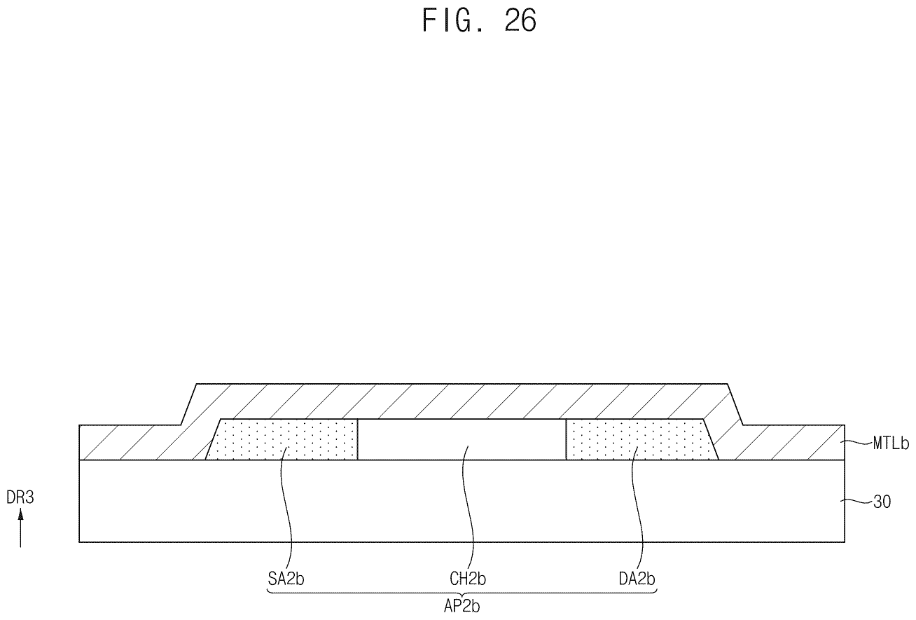

Referring to FIG. 26, a metal layer MTLb may be formed on the second active pattern AP2b formed with the second source region SA2b and the second drain region DA2b. In an embodiment, the metal layer MTLb may be formed using titanium (Ti), copper (Cu), or the like. In an embodiment, the metal layer MTLb may be formed by a sputtering process.

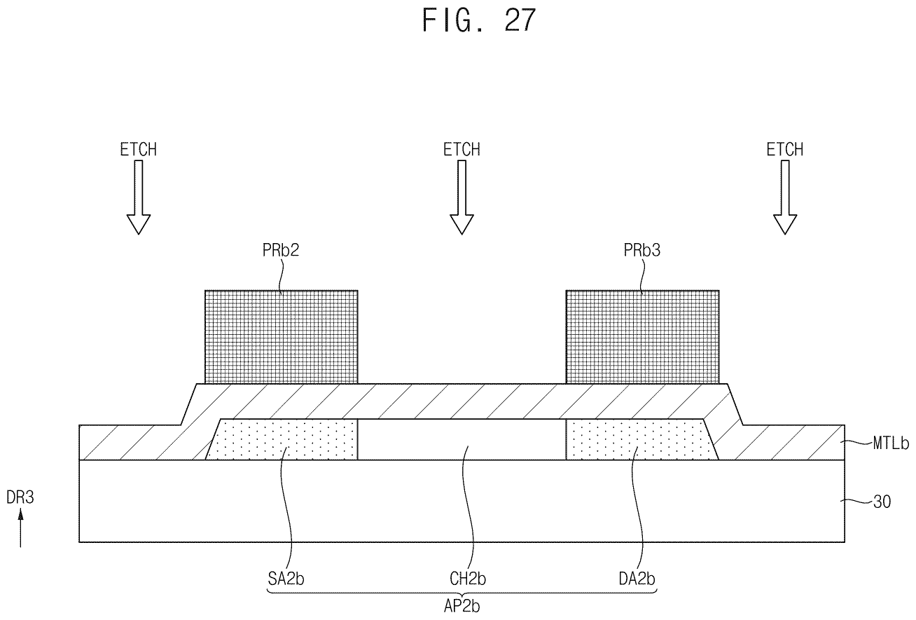

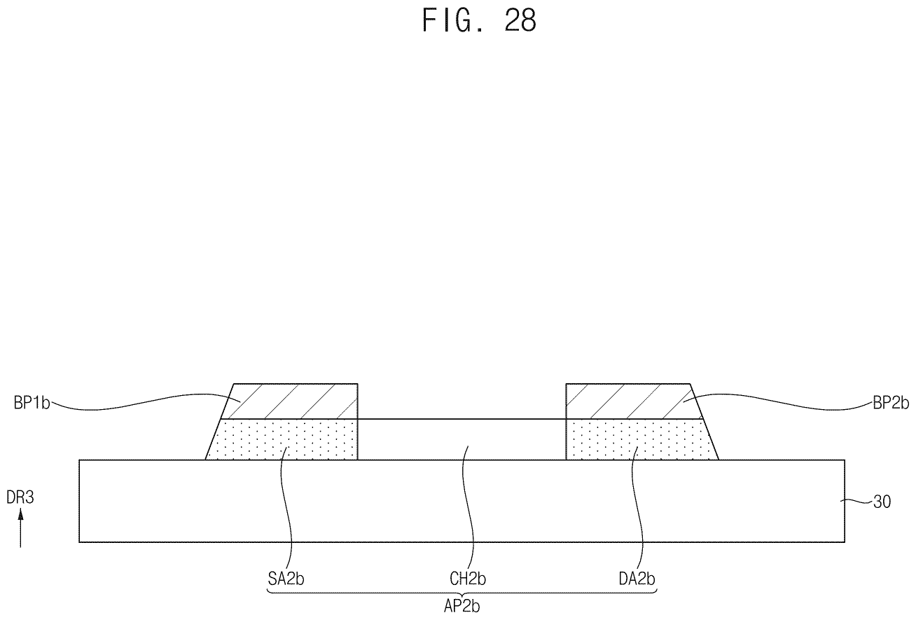

Referring to FIGS. 27 and 28, photoresist patterns PRb2 and PRb3 of FIG. 27 overlapping the second source region SA2b and the second drain region DA2b of the second active pattern AP2b, respectively, may be formed on the metal layer MTLb. The exposed metal layer MTLb may be etched using the photoresist patterns PRb2 and PRb3 as an etch mask. As a result, the first barrier pattern BP1b and the second barrier pattern BP2b may be formed. At this time, the etching process may be performed by various methods, such as wet etching, dry etching, or the like. After the first barrier pattern BP1b and the second barrier pattern BP2b are formed, the photoresist patterns PRb2 and PRb3 may be removed. That is, the barrier patterns are provided after the providing of the doped material layer.

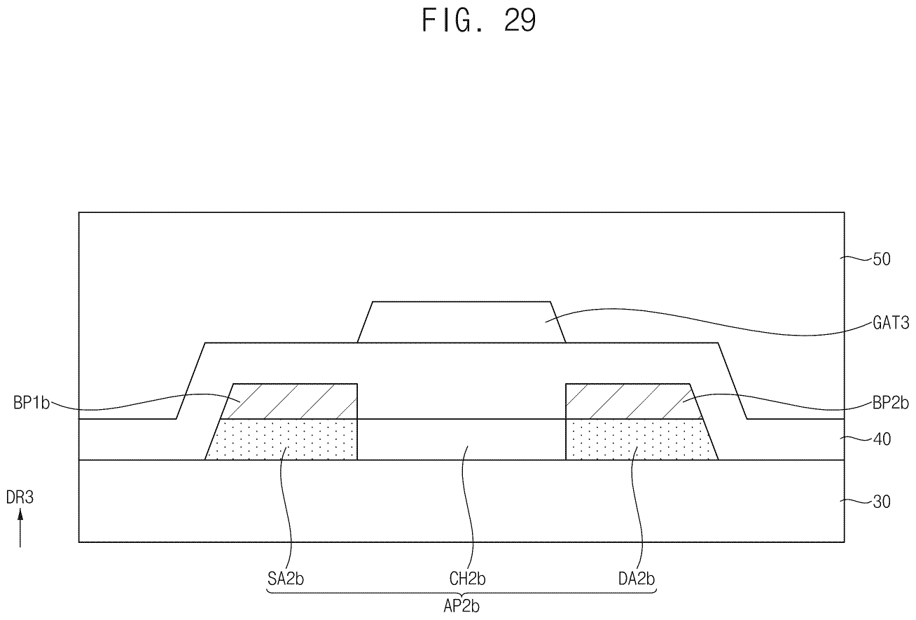

Referring to FIG. 29, the fourth insulating layer 40 covering the second active pattern AP2b, the first barrier pattern BP1b, and the second barrier pattern BP2b, the third gate electrode GAT3, and the fifth insulating layer 50 may be sequentially formed on the third insulating layer 30.

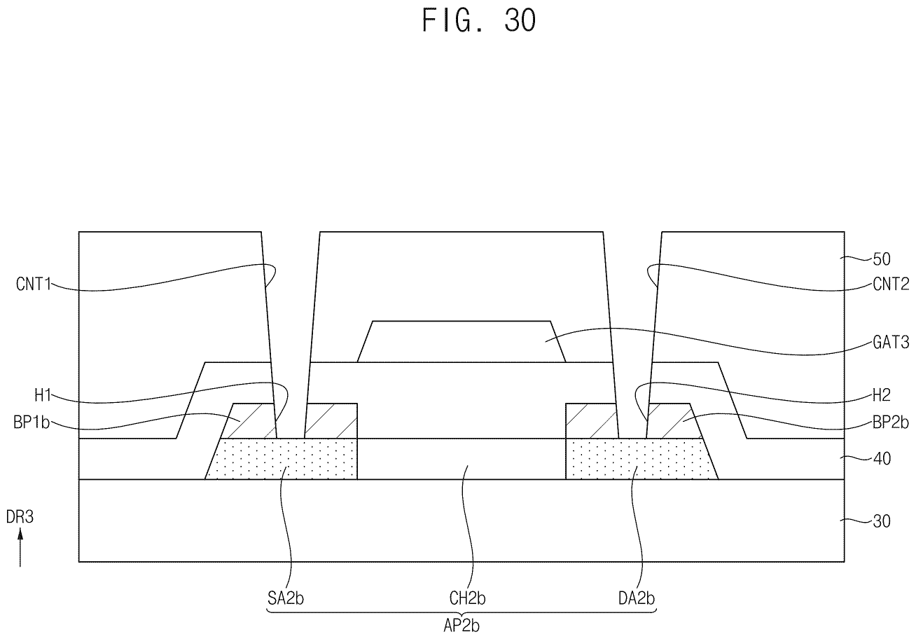

Referring to FIG. 30, at a distance from edges (or end surfaces) of the barrier patterns, a first contact hole CNT1 exposing a portion of the upper surface of the second source region SA2b of the second active pattern AP2b and a second contact hole CNT2 exposing a portion of the upper surface of the second drain region DA2b of the second active pattern AP2b may be formed. The first contact hole CNT1 may penetrate the first barrier pattern BP1b, the fourth insulating layer 40, and the fifth insulating layer 50 in the third direction DR3, and the second contact hole CNT2 may penetrate the second barrier pattern BP2b, the fourth insulating layer 40, and the fifth insulating layer 50 in the third direction DR3. That is, the first through hole H1 may be formed in the first barrier pattern BP1b, and the second through hole H2 may be formed in the second barrier pattern BP2b.

Subsequently, as shown in FIG. 22, the display device DDb may be manufactured by sequentially forming the first and second source electrodes SE1 and SE2, the first and second drain electrodes DE1 and DE2, the first organic insulating layer VIA1, connection electrode CE, the second organic insulating layer VIA2, the first electrode E1, the pixel defining layer PDL, the middle layer ML, and the second electrode E2 on the fifth insulating layer 50.

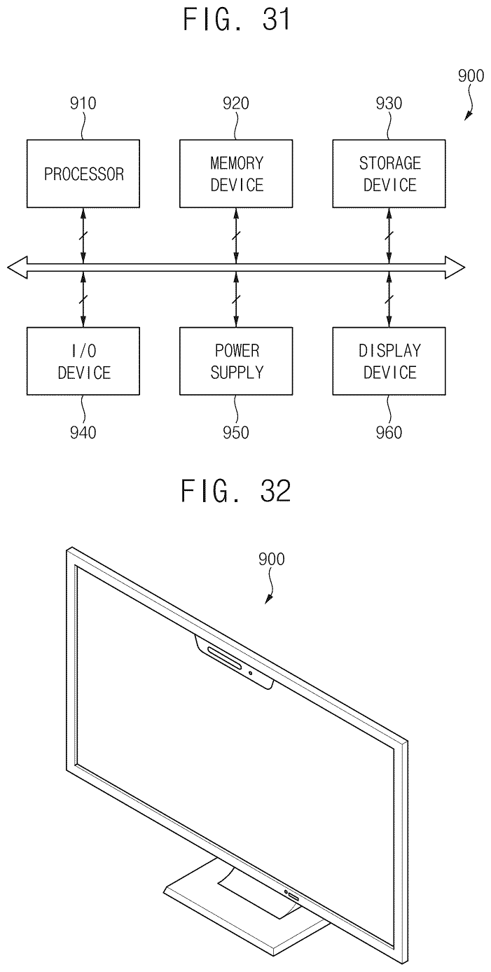

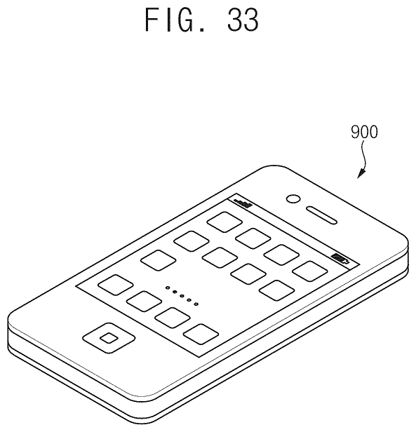

FIG. 31 is a block diagram illustrating an electronic device 900 according to an embodiment. FIG. 32 is a diagram illustrating an example in which the electronic device 900 of FIG. 31 is implemented as a television. FIG. 33 is a diagram illustrating an example in which the electronic device 900 of FIG. 31 is implemented as a smartphone.

Referring to FIGS. 31, 32, and 33, in an embodiment, an electronic device 900 may include a processor 910, a memory device 920, a storage device 930, an input/output device 940, a power supply 950, and a display device 960. In this case, the display device 960 may correspond to one or more of the display devices DD, DDa, and DDb described above. The electronic device 900 may further include several ports capable of communicating with a video card, sound card, memory card, USB device, or the like.

In an embodiment, as shown in FIG. 32, the electronic device 900 may be implemented as a television. In an embodiment, as shown in FIG. 33, the electronic device 900 may be implemented as a smartphone. However, the electronic device 900 is not limited thereto, and for example, the electronic device 900 may be implemented as a mobile phone, video phone, smart pad, smart watch, tablet PC, vehicle navigation, computer monitor, laptop, head mounted display (HMD), or the like.

The processor 910 may perform specific calculations or tasks. The processor 910 may control the display device 960. In an embodiment, the processor 910 may be a microprocessor, a central processing unit (CPU), an application processor (AP), or the like. The processor 910 may be connected to other components through an address bus, control bus, data bus, or the like. The processor 910 may also be connected to an expansion bus, such as a peripheral component interconnect (PCI) bus, or the like.

The memory device 920 may store data necessary for the operation of the electronic device 900. For example, the memory device 920 may include non-volatile memory devices, such as erasable programmable read-only memory (EPROM) devices, electrically erasable programmable read-only memory (EEPROM) devices, flash memory devices, phase change random access memory (PRAM) devices, resistance random access memory (RRAM) devices, nano floating gate memory (NFGM) devices, polymer random access memory (PoRAM) devices, magnetic random access memory (MRAM), ferroelectric random access memory (FRAM), or the like and/or volatile memory devices, such as dynamic random access memory (DRAM) devices, static access memory (SRAM) device, mobile DRAM devices, or the like.

The storage device 930 may include a solid state drive (SSD), a hard disk drive (HDD), a CD-ROM, or the like.

The input/output device 940 may include input means, such as a keyboard, keypad, touch pad, touch screen, mouse, or the like, and output means, such as a speaker, printer, or the like.

The power supply 950 may supply power necessary for the operation of the electronic device 900. Display device 960 may be connected to other components via buses or other communication links. In an embodiment, the display device 960 may be included in the input/output device 940.

The present disclosure can be applied to display devices and electronic devices including the same. For example, the present disclosure can be applied to high-resolution smartphones, mobile phones, smart pads, smart watches, tablet PCs, vehicle navigation systems, televisions, computer monitors, laptops, or the like.

In one or more embodiment, a display device includes a transistor on the substrate SUB, the transistor including an active pattern including an oxide semiconductor, a source region, a drain region, a channel region between the source region and the drain region, and a boundary between the channel region and each of the source region and the drain region, respectively, a barrier pattern layer which is on the active pattern and includes a hydrogen-blocking material, the barrier pattern including a first barrier pattern which is disposed at the boundary between the channel region and the source region, and a second barrier pattern which is disposed at the boundary between the channel region and the drain region, a gate insulating layer on the active pattern, the first barrier pattern and the second barrier pattern, and a gate electrode on the gate insulating layer, and a light emitting element LED on the gate electrode, and a processor which controls the display device.

Referring to FIGS. 2 and 3 and FIGS. 16 and 17, for example, grooves may be defined in the active pattern, the grooves including a first groove which extends to the boundary between the channel region and the source region and in which the first barrier pattern is disposed, and a second groove which extends to the boundary between the channel region and the drain region, is spaced apart from the first groove and in which the second barrier pattern is disposed, the first barrier pattern which is in the first groove may block hydrogen diffusion from the gate insulating layer to the channel region via the source region, and the second barrier pattern which is in the second groove may block hydrogen diffusion from the gate insulating layer to the channel region via the drain region.

Here, the display device may further include a barrier layer IB which includes an inorganic material layer between the active pattern and the gate insulating layer, extended into each of the first groove and the second groove, and extended further than the active pattern in a direction along the substrate, the first barrier pattern between the barrier layer and the gate insulating layer, in the first groove, and the second barrier pattern between the barrier layer and the gate insulating layer, in the second groove.

Referring to FIGS. 22 and 23, for example, the first barrier pattern may extend to the boundary between the channel region and the source region and block hydrogen diffusion from the interlayer insulating layer to the source region, and the second barrier pattern may extend to the boundary between the channel region and the drain region and block hydrogen diffusion from the interlayer insulating layer to the drain region.

Although described above with reference to embodiments of the present disclosure, those of ordinary skill in the art will understand that the present disclosure may be variously modified and changed without departing from the spirit and scope of the present disclosure described in the following claims.

What is claimed is:

1. A display device comprising:
a substrate;
a transistor on the substrate, the transistor comprising:
an active pattern including an oxide semiconductor and in which grooves are defined, the active pattern including:
a source region, a drain region, and a channel region between the source region and the drain region, and
among the grooves, a first groove between the source region and the channel region, and a second groove between the drain region and the channel region;
a barrier pattern layer on the active pattern, the barrier pattern layer including:
a first barrier pattern in the first groove of the active pattern; and
a second barrier pattern in the second groove of the active pattern;
a gate insulating layer on the active pattern, the first barrier pattern and the second barrier pattern; and
a gate electrode on the gate insulating layer; and
a light emitting element on the gate electrode.

2. The display device of claim 1, wherein a depth of each of the first groove and the second groove is less than a thickness of the active pattern.

3. The display device of claim 1, wherein each of the first barrier pattern and the second barrier pattern contacts the active pattern.

4. The display device of claim 1, further comprising:
a barrier layer which includes an inorganic material layer between the active pattern and the gate insulating layer, and extended further than the active pattern in a direction along the substrate.

5. The display device of claim 4, wherein
the barrier layer extends into the first groove and the second groove,
the first barrier pattern is between the barrier layer and the gate insulating layer, in the first groove, and
the second barrier pattern is between the barrier layer and the gate insulating layer, in the second groove.

6. The display device of claim 1, wherein
the barrier pattern layer includes a hydrogen-blocking material,
the first barrier pattern which is in the first groove blocks hydrogen diffusion from the gate insulating layer to the channel region via the source region, and
the second barrier pattern which is in the second groove blocks hydrogen diffusion from the gate insulating layer to the channel region via the drain region.

7. The display device of claim 1, wherein each of the first barrier pattern and the second barrier pattern includes a metal.

8. The display device of claim 7, wherein each of the first barrier pattern and the second barrier pattern includes titanium or copper.

9. The display device of claim 1, further comprising:
an interlayer insulating layer on the gate electrode;
a source electrode of the transistor which is on the interlayer insulating layer and connected to the transistor at the source region; and
a drain electrode of the transistor which is on the interlayer insulating layer and connected to the transistor at the drain region.

10. A display device comprising:
a substrate;
a transistor on the substrate, the transistor comprising:
an active pattern including an oxide semiconductor, a source region, a drain region, and a channel region between the source region and the drain region;
a barrier pattern layer on the active pattern, the barrier pattern layer including:
a first barrier pattern overlapping the source region of the active pattern; and
a second barrier pattern overlapping the drain region of the active pattern;
a gate insulating layer on the active pattern, the first barrier pattern, and the second barrier pattern; and
a gate electrode on the gate insulating layer; and
a light emitting element on the gate electrode.

11. The display device of claim 10, wherein the first barrier pattern and the second barrier pattern contacts an upper surface of the active pattern at the source region and the drain region, respectively.

12. The display device of claim 10, further comprising:
an interlayer insulating layer on the gate electrode;
a source electrode of the transistor which is on the interlayer insulating layer and connected to the transistor at the source region; and
a drain electrode of the transistor which is on the interlayer insulating layer and connected to the transistor at the drain region, and
a first through hole which is defined through a thickness of the first barrier pattern, exposes the source region to outside the first barrier pattern and in which the source electrode contacts the source region, and
a second through hole which is defined through a thickness of the second barrier pattern, exposes the drain region to outside the second barrier pattern and in which the drain electrode contacts the drain region.

13. The display device of claim 12, wherein
the barrier pattern layer includes a hydrogen-blocking material,
a boundary is define between the channel region, and each of the source region and the drain region, respectively,
the first barrier pattern extends to the boundary between the channel region and the source region and blocks hydrogen diffusion from the interlayer insulating layer to the source region, and
the second barrier pattern extends to the boundary between the channel region and the drain region and blocks hydrogen diffusion from the interlayer insulating layer to the drain region.

14. The display device of claim 10, wherein each of the first barrier pattern and the second barrier pattern includes a metal.

15. An electronic device comprising:
a display device including:
a substrate;
a transistor on the substrate, the transistor comprising:
an active pattern including an oxide semiconductor, a source region, a drain region, a channel region between the source region and the drain region, and a boundary between the channel region and each of the source region and the drain region, respectively;
a barrier pattern layer which is on the active pattern and includes a hydrogen-blocking material, the barrier pattern layer including:
a first barrier pattern which is disposed at the boundary between the channel region and the source region; and
a second barrier pattern which is disposed at the boundary between the channel region and the drain region;
a gate insulating layer on the active pattern, the first barrier pattern and the second barrier pattern; and
a gate electrode on the gate insulating layer; and
a light emitting element on the gate electrode; and
a processor which controls the display device.

16. The electronic device of claim 15, wherein
grooves are defined in the active pattern, the grooves including:
a first groove which extends to the boundary between the channel region and the source region and in which the first barrier pattern is disposed, and
a second groove which extends to the boundary between the channel region and the drain region, is spaced apart from the first groove and in which the second barrier pattern is disposed,
the first barrier pattern which is in the first groove blocks hydrogen diffusion from the gate insulating layer to the channel region via the source region, and
the second barrier pattern which is in the second groove blocks hydrogen diffusion from the gate insulating layer to the channel region via the drain region.

17. The electronic device of claim 15, wherein each of the first barrier pattern and the second barrier pattern contacts the active pattern.

18. The electronic device of claim 16, wherein the display device further includes:
a barrier layer which includes an inorganic material layer between the active pattern and the gate insulating layer, extended into each of the first groove and the second groove, and extended further than the active pattern in a direction along the substrate,
the first barrier pattern between the barrier layer and the gate insulating layer, in the first groove, and
the second barrier pattern between the barrier layer and the gate insulating layer, in the second groove.

19. The electronic device of claim 15, wherein the display device further includes:
an interlayer insulating layer on the gate electrode,
a source electrode of the transistor which is on the interlayer insulating layer and connected to the transistor at the source region,
a drain electrode of the transistor which is on the interlayer insulating layer and connected to the transistor at the drain region,
a first through hole which is defined through a thickness of the first barrier pattern, exposes the source region to outside the first barrier pattern and in which the source electrode contacts the source region, and
a second through hole which is defined through a thickness of the second barrier pattern, exposes the drain region to outside the second barrier pattern and in which the drain electrode contacts the drain region.

20. The electronic device of claim 19, wherein
the first barrier pattern extends to the boundary between the channel region and the source region and blocks hydrogen diffusion from the interlayer insulating layer to the source region, and
the second barrier pattern extends to the boundary between the channel region and the drain region and blocks hydrogen diffusion from the interlayer insulating layer to the drain region.
